(19) United States
(12) Patent Application Publication
(10) Pub. No.: US 2026/0180716 A1
(43) Pub. Date: Jun. 25, 2026

(54) INFORMATION INDICATIONS FOR RAPTOR CODES

(71) Applicant: QUALCOMM Incorporated, San Diego, CA (US)

(72) Inventors: Kangqi LIU, San Diego, CA (US); Changlong XU, Beijing (CN); Jian LI, Shanghai (CN); Liangming WU, Beijing (CN); Hao XU, Beijing (CN)

(21) Appl. No.: 19/128,139

(22) PCT Filed: Dec. 22, 2022
(86) PCT No.: PCT/CN2022/141004

§ 371 Date: May 7, 2025

(51) Int. Cl. H04L 1/00; H04W 72/1273

(52) U.S. Cl. CPC H04L 1/0064; H04W 72/1273

(57) ABSTRACT

Methods, systems, and devices for wireless communications are described. An encoding device (e. g., a network entity or user equipment (UE)) may communicate indications of encoded symbol identifiers (ESI), source block numbers (SBN), or both with a decoding device in a downlink control information (DCI). As examples, the indications of the SBN and/or ESIs may be transmitted using either an unused or repurposed field in the downlink control information (DCI) that schedules a transmission that includes the encoded symbols or in a new DCI that piggybacks on a downlink shared channel transmission that includes the encoded symbols. Additionally, or alternatively, in a first option, the ESI may be explicitly indicated by the DCI. In another option, the network entity may indicate a configuration (e. g., via radio resource control messaging) for implicitly determining the ESI based on information conveyed in the DCI.

### CROSS REFERENCE

The present Application is a 371 national stage filing of International PCT Application No. PCT/CN2022/141004 by LIU et al. entitled “INFORMATION INDICATIONS FOR RAPTOR CODES,” filed Dec. 22, 2022, which is assigned to the assignee hereof, and which is expressly incorporated by reference in its entirety herein.

### INTRODUCTION

The following relates to wireless communications relating to including information indication(s) for Raptor codes.

Wireless communications systems are widely deployed to provide various types of communication content such as voice, video, packet data, messaging, broadcast, and so on. These systems may be capable of supporting communication with multiple users by sharing the available system resources (e.g., time, frequency, and power). Examples of such multiple-access systems include fourth generation (4G) systems such as Long Term Evolution (LTE) systems, LTE-Advanced (LTE-A) systems, or LTE-A Pro systems, and fifth generation (5G) systems which may be referred to as New Radio (NR) systems. These systems may employ technologies such as code division multiple access (CDMA), time division multiple access (TDMA), frequency division multiple access (FDMA), orthogonal FDMA (OFDMA), or discrete Fourier transform spread orthogonal frequency division multiplexing (DFT-S-OFDM). A wireless multiple-access communications system may include one or more base stations, each supporting wireless communication for communication devices, which may be known as user equipment (UE).

### SUMMARY

The described techniques relate to improved methods, systems, devices, and apparatuses that support information indications for Raptor codes. For example, the described techniques provide for an encoding device (e.g., a network entity or user equipment (UE)) to communicate indications of encoded symbol identifier(s) (ESI) and/or a source block numbers (SBN) for encoded symbols associated via a rateless code with a set of source symbols with a decoding device in a downlink control information (DCI). As examples, the indications of the SBN and/or ESIs may be transmitted using either an unused or repurposed field in the downlink control information (DCI) that schedules a transmission that includes the encoded symbols or in a new DCI that piggybacks on a downlink shared channel transmission that includes the encoded symbols. Additionally, or alternatively, in a first option, the ESI(s) may be explicitly indicated by the DCI. In another option, the network entity may indicate a configuration (e.g., via radio resource control (RRC) messaging) for implicitly determining the ESI based on information conveyed in the DCI.

A method for wireless communications at a first network node is described. The method may include participating in communication of DCI, where the DCI includes an indication of a SBN associated with a source block for a set of multiple source symbols, where the DCI includes scheduling information for a transmission including one or more encoded symbols derived from the set of multiple source symbols, where the DCI is included in a downlink shared channel transmission that includes the one or more encoded symbols, or the DCI includes the indication in a repurposed field, receiving the one or more encoded symbols, where each respective encoded symbol of the one or more encoded symbols is associated, via a rateless code, with a respective corresponding set of source symbols of the set of multiple source symbols, and decoding, based on the SBN, the one or more encoded symbols to determine the set of multiple source symbols.

An first network node for wireless communications is described. The first network node may include: a memory; and at least one processor coupled to the memory, where the at least one processor is configured to participate in communication of DCI, where the DCI includes an indication of a SBN associated with a source block for a set of multiple source symbols, where the DCI includes scheduling information for a transmission including one or more encoded symbols derived from the set of multiple source symbols, where the DCI is included in a downlink shared channel transmission that includes the one or more encoded symbols, or the DCI includes the indication in a repurposed field, receive the one or more encoded symbols, where each respective encoded symbol of the one or more encoded symbols is associated, via a rateless code, with a respective corresponding set of source symbols of the set of multiple source symbols, and decode, based on the SBN, the one or more encoded symbols to determine the set of multiple source symbols.

Another apparatus for wireless communications at a first network node is described. The apparatus may include means for participating in communication of DCI, where the DCI includes an indication of a SBN associated with a source block for a set of multiple source symbols, where the DCI includes scheduling information for a transmission including one or more encoded symbols derived from the set of multiple source symbols, where the DCI is included in a downlink shared channel transmission that includes the one or more encoded symbols, or the DCI includes the indication in a repurposed field, means for receiving the one or more encoded symbols, where each respective encoded symbol of the one or more encoded symbols is associated, via a rateless code, with a respective corresponding set of source symbols of the set of multiple source symbols, and means for decoding, based on the SBN, the one or more encoded symbols to determine the set of multiple source symbols.

A non-transitory computer-readable medium storing code for wireless communications at a first network node is described. The code may include instructions executable by a processor to participate in communication of DCI, where the DCI includes an indication of a SBN associated with a source block for a set of multiple source symbols, where the DCI includes scheduling information for a transmission including one or more encoded symbols derived from the set of multiple source symbols, where the DCI is included in a downlink shared channel transmission that includes the one or more encoded symbols, or the DCI includes the indication in a repurposed field, receive the one or more encoded symbols, where each respective encoded symbol of the one or more encoded symbols is associated, via a rateless code, with a respective corresponding set of source symbols of the set of multiple source symbols, and decode, based on the SBN, the one or more encoded symbols to determine the set of multiple source symbols.

In some examples of the method, apparatuses, and non-transitory computer-readable medium described herein, decoding the one or more encoded symbols may include operations, features, means, or instructions for decoding the one or more encoded symbols based on one or more ESIs, where the DCI includes an indication of the one or more ESIs that correspond to the one or more encoded symbols.

Some examples of the method, apparatuses, and non-transitory computer-readable medium described herein may further include operations, features, means, or instructions for participating in communication of a RRC message, where the RRC message indicates one or more parameters and determining, based on the one or more parameters and first information included in the DCI, one or more ESIs that correspond to the one or more encoded symbols, where decoding the one or more encoded symbols includes decoding the one or more encoded symbols based on the one or more ESIs.

In some examples of the method, apparatuses, and non-transitory computer-readable medium described herein, the first information includes the scheduling information.

In some examples of the method, apparatuses, and non-transitory computer-readable medium described herein, the scheduling information includes a position of one or more resource blocks, a system frame number, a slot number, or a symbol number.

In some examples of the method, apparatuses, and non-transitory computer-readable medium described herein, the first information includes a DCI sequence corresponding to the DCI.

In some examples of the method, apparatuses, and non-transitory computer-readable medium described herein, participating in the communication of the DCI may include operations, features, means, or instructions for receiving the DCI.

In some examples of the method, apparatuses, and non-transitory computer-readable medium described herein, participating in the communication of the DCI may include operations, features, means, or instructions for transmitting the DCI.

In some examples of the method, apparatuses, and non-transitory computer-readable medium described herein, decoding the one or more encoded symbols may include operations, features, means, or instructions for determining, based on a Raptor code, the set of multiple source symbols from the one or more encoded symbols, where the rateless code may be the Raptor code.

A method for wireless communications at a first network node is described. The method may include participating in communication of DCI, where the DCI includes an indication of a SBN associated with a source block for a set of multiple source symbols, where the DCI includes scheduling information for a transmission including one or more encoded symbols derived from the set of multiple source symbols, where the DCI is included in a downlink shared channel transmission that includes the one or more encoded symbols, or the DCI includes the indication in a repurposed field and transmitting the one or more encoded symbols, where each respective encoded symbol of the one or more encoded symbols is associated, via a rateless code, with a corresponding set of source symbols of the set of multiple source symbols.

An first network node for wireless communications is described. The first network node may include: a memory; and at least one processor coupled to the memory, where the at least one processor is configured to participate in communication of DCI, where the DCI includes an indication of a SBN associated with a source block for a set of multiple source symbols, where the DCI includes scheduling information for a transmission including one or more encoded symbols derived from the set of multiple source symbols, where the DCI is included in a downlink shared channel transmission that includes the one or more encoded symbols, or the DCI includes the indication in a repurposed field and transmit the one or more encoded symbols, where each respective encoded symbol of the one or more encoded symbols is associated, via a rateless code, with a corresponding set of source symbols of the set of multiple source symbols.

Another apparatus for wireless communications at a first network node is described. The apparatus may include means for participating in communication of DCI, where the DCI includes an indication of a SBN associated with a source block for a set of multiple source symbols, where the DCI includes scheduling information for a transmission including one or more encoded symbols derived from the set of multiple source symbols, where the DCI is included in a downlink shared channel transmission that includes the one or more encoded symbols, or the DCI includes the indication in a repurposed field and means for transmitting the one or more encoded symbols, where each respective encoded symbol of the one or more encoded symbols is associated, via a rateless code, with a corresponding set of source symbols of the set of multiple source symbols.

A non-transitory computer-readable medium storing code for wireless communications at a first network node is described. The code may include instructions executable by a processor to participate in communication of DCI, where the DCI includes an indication of a SBN associated with a source block for a set of multiple source symbols, where the DCI includes scheduling information for a transmission including one or more encoded symbols derived from the set of multiple source symbols, where the DCI is included in a downlink shared channel transmission that includes the one or more encoded symbols, or the DCI includes the indication in a repurposed field and transmit the one or more encoded symbols, where each respective encoded symbol of the one or more encoded symbols is associated, via a rateless code, with a corresponding set of source symbols of the set of multiple source symbols.

In some examples of the method, apparatuses, and non-transitory computer-readable medium described herein, the DCI includes an indication of one or more ESIs that correspond to the one or more encoded symbols.

Some examples of the method, apparatuses, and non-transitory computer-readable medium described herein may further include operations, features, means, or instructions for participating in communication of a RRC message, where the RRC message indicates one or more parameters for determination of one or more ESIs that correspond to the one or more encoded symbols.

In some examples of the method, apparatuses, and non-transitory computer-readable medium described herein, participating in the communication of the DCI may include operations, features, means, or instructions for receiving the DCI.

In some examples of the method, apparatuses, and non-transitory computer-readable medium described herein, participating in the communication of the DCI may include operations, features, means, or instructions for transmitting the DCI.

Some examples of the method, apparatuses, and non-transitory computer-readable medium described herein may further include operations, features, means, or instructions for generating, based on a Raptor code, the one or more encoded symbols from the set of multiple source symbols, where the rateless code may be the Raptor code.

### BRIEF DESCRIPTION OF THE DRAWINGS

FIG. 1 illustrates an example of a wireless communications system that supports information indications for Raptor codes in accordance with one or more aspects of the present disclosure.

FIG. 2 illustrates an example of a wireless communications system that supports information indications for Raptor codes in accordance with one or more aspects of the present disclosure.

FIG. 3 illustrates an example of a Raptor encoding scheme that supports information indications for Raptor codes in accordance with one or more aspects of the present disclosure.

FIG. 4 illustrates an example of a decoding scheme that supports information indications for Raptor codes in accordance with one or more aspects of the present disclosure.

FIG. 5 illustrates examples of resource diagrams that supports information indications for Raptor codes in accordance with one or more aspects of the present disclosure.

FIG. 6 illustrates an example of a process flow that supports information indications for Raptor codes in accordance with one or more aspects of the present disclosure.

FIGS. 7 and 8 illustrate block diagrams of devices that support information indications for Raptor codes in accordance with one or more aspects of the present disclosure.

FIG. 9 illustrates a block diagram of a communications manager that supports information indications for Raptor codes in accordance with one or more aspects of the present disclosure.

FIG. 11 illustrates a diagram of a system including a UE that supports information indications for Raptor codes in accordance with one or more aspects of the present disclosure.

FIG. 10 illustrates a diagram of a system including a network entity that supports information indications for Raptor codes in accordance with one or more aspects of the present disclosure.

FIGS. 12 through 14 illustrate flowcharts showing methods that support information indications for Raptor codes in accordance with one or more aspects of the present disclosure.

### DETAILED DESCRIPTION

A first network node, such as a user equipment (UE) in downlink or a network entity in uplink, may receive a transmission that includes a set of encoded symbols from a second network node, such as a network entity in downlink or a UE in uplink. The encoded symbols may be encoded according to a Raptor code. In a Raptor code, a number of source symbols may be identified for transmission. The source symbols may be encoded into a plurality of encoded symbols which are actually transmitted (instead of transmitting the source symbols directly). Each encoded symbol may be associated with one or more of the source symbols. When a receiving network node (e.g., a decoding device) receives a sufficient number of encoded symbols, the receiving network node may decode the encoded symbols to determine the source symbols. The transmitted one or multiple encoded symbols may include a source block number (SBN), linking the transmitted encoded symbol(s) to the source symbols, and an encoded symbol identifier (ESI) for each encoded symbol in the transmission. However, including the SBN and ESI(s) in the packets of the transmission may lead to increased overhead, which may be undesirable when using Raptor codes at the radio-link control (RLC) or physical (PHY) layer. In addition, soft-combining of received packets is not then available if the header is not received correctly-because failure to decode the header means that the symbol information is unknown.

Accordingly, an encoding device and a decoding device may communicate indications of ESI, SBN, or both in a downlink control information (DCI) (e.g., instead of in the headers of the packets of the transmission that includes the encoded symbols). As examples, the indications of the SBN and/or ESIs may be transmitted using either an unused or repurposed field in the DCI that schedules a transmission that includes the encoded symbols, or in a new DCI that piggybacks on a downlink shared channel transmission that includes the encoded symbols. Additionally, or alternatively, in a first option, the ESI may be explicitly indicated by the DCI. In another option, the network entity may indicate a configuration (e.g., via radio resource control (RRC) messaging) for implicitly determining the ESI based on information conveyed in the DCI. The configuration message may include parameters to allow a receiving device to determine the ESIs from scheduling information (e.g., a position of resource blocks or a slot frame number (SFN)) or via a DCI sequence. For example, the UE may receive the scheduling information and may generate ESIs based on a function of the scheduling information.

Aspects of the disclosure are initially described in the context of wireless communications systems. Additional aspects of the disclosure are described in the context of a Raptor encoding scheme, a decoding scheme, resource diagrams, and a process flow. Aspects of the disclosure are further illustrated by and described with reference to apparatus diagrams, system diagrams, and flowcharts that relate to information indications for Raptor codes.

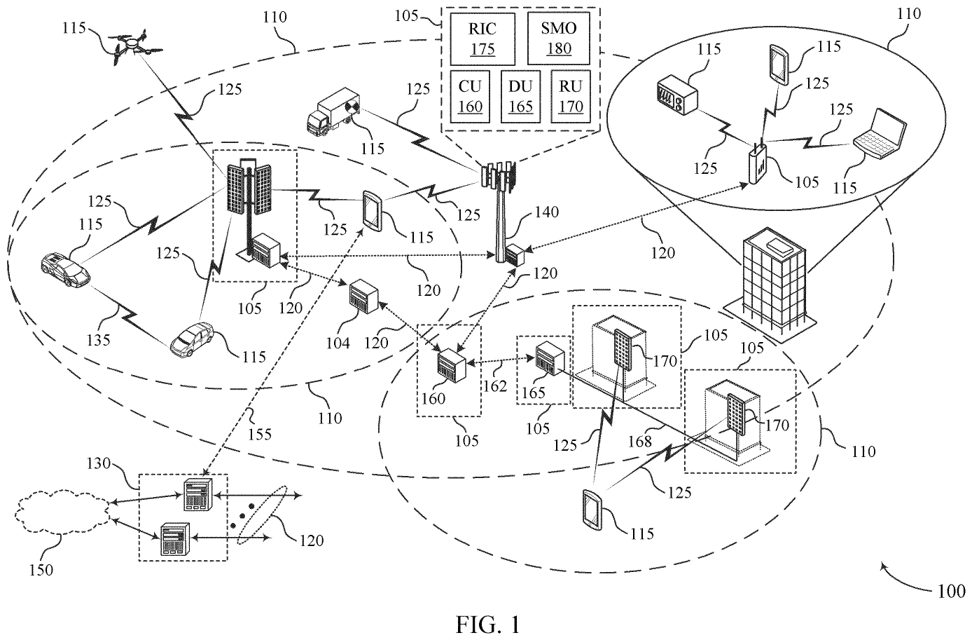

FIG. 1 illustrates an example of a wireless communications system 100 that supports information indications for Raptor codes in accordance with one or more aspects of the present disclosure. The wireless communications system 100 may include one or more network entities 105, one or more UEs 115, and a core network 130. In some aspects, the wireless communications system 100 may be a Long Term Evolution (LTE) network, an LTE-Advanced (LTE-A) network, an LTE-A Pro network, a New Radio (NR) network, or a network operating in accordance with other systems and radio technologies, including future systems and radio technologies not explicitly mentioned herein.

The network entities 105 may be dispersed throughout a geographic area to form the wireless communications system 100 and may include devices in different forms or having different capabilities. In various examples, a network entity 105 may be referred to as a network element, a mobility element, a radio access network (RAN) node, or network equipment, among other nomenclature. In some aspects, network entities 105 and UEs 115 may wirelessly communicate via one or more communication links 125 (e.g., a radio frequency (RF) access link). For example, a network entity 105 may support a coverage area 110 (e.g., a geographic coverage area) over which the UEs 115 and the network entity 105 may establish one or more communication links 125. The coverage area 110 may be an example of a geographic area over which a network entity 105 and a UE 115 may support the communication of signals according to one or more radio access technologies (RATs).

The UEs 115 may be dispersed throughout a coverage area 110 of the wireless communications system 100, and each UE 115 may be stationary, or mobile, or both at different times. The UEs 115 may be devices in different forms or having different capabilities. Some example UEs 115 are illustrated in FIG. 1. The UEs 115 described herein may be capable of supporting communications with various types of devices, such as other UEs 115 or network entities 105, as shown in FIG. 1.

As described herein, a node (which may be referred to as a node, a network node, a network entity, or a wireless node) may include, be, or be included in (e.g., be a component of) a base station (e.g., any base station described herein), a UE (e.g., any UE described herein), a network controller, an apparatus, a device, a computing system, an integrated access and backhauling (IAB) node, a distributed unit (DU), a central unit (CU), a remote/radio unit (RU) (which may also be referred to as a remote radio unit (RRU)), and/or another processing entity configured to perform any of the techniques described herein. For example, a network node may be a UE. As another example, a network node may be a base station or network entity. As another example, a first network node may be configured to communicate with a second network node or a third network node. In one aspect of this example, the first network node may be a UE, the second network node may be a base station, and the third network node may be a UE. In another aspect of this example, the first network node may be a UE, the second network node may be a base station, and the third network node may be a base station. In yet other aspects of this example, the first, second, and third network nodes may be different relative to these examples. Similarly, reference to a UE, base station, apparatus, device, computing system, or the like may include disclosure of the UE, base station, apparatus, device, computing system, or the like being a network node. For example, disclosure that a UE is configured to receive information from a base station also discloses that a first network node is configured to receive information from a second network node. Consistent with this disclosure, once a specific example is broadened in accordance with this disclosure (e.g., a UE is configured to receive information from a base station also discloses that a first network node is configured to receive information from a second network node), the broader example of the narrower example may be interpreted in the reverse, but in a broad open-ended way. In the example above where a UE is configured to receive information from a base station also discloses that a first network node is configured to receive information from a second network node, the first network node may refer to a first UE, a first base station, a first apparatus, a first device, a first computing system, a first set of one or more one or more components, a first processing entity, or the like configured to receive the information; and the second network node may refer to a second UE, a second base station, a second apparatus, a second device, a second computing system, a second set of one or more components, a second processing entity, or the like.

As described herein, communication of information (e.g., any information, signal, or the like) may be described in various aspects using different terminology. Disclosure of one communication term includes disclosure of other communication terms. For example, a first network node may be described as being configured to transmit information to a second network node. In this example and consistent with this disclosure, disclosure that the first network node is configured to transmit information to the second network node includes disclosure that the first network node is configured to provide, send, output, communicate, or transmit information to the second network node. Similarly, in this example and consistent with this disclosure, disclosure that the first network node is configured to transmit information to the second network node includes disclosure that the second network node is configured to receive, obtain, or decode the information that is provided, sent, output, communicated, or transmitted by the first network node.

In some aspects, network entities 105 may communicate with the core network 130, or with one another, or both. For example, network entities 105 may communicate with the core network 130 via one or more backhaul communication links 120 (e.g., in accordance with an S1, N2, N3, or other interface protocol). In some aspects, network entities 105 may communicate with one another via a backhaul communication link 120 (e.g., in accordance with an X2, Xn, or other interface protocol) either directly (e.g., directly between network entities 105) or indirectly (e.g., via a core network 130). In some aspects, network entities 105 may communicate with one another via a midhaul communication link 162 (e.g., in accordance with a midhaul interface protocol) or a fronthaul communication link 168 (e.g., in accordance with a fronthaul interface protocol), or any combination thereof. The backhaul communication links 120, midhaul communication links 162, or fronthaul communication links 168 may be or include one or more wired links (e.g., an electrical link, an optical fiber link), one or more wireless links (e.g., a radio link, a wireless optical link), among other examples or various combinations thereof. A UE 115 may communicate with the core network 130 via a communication link 155.

One or more of the network entities 105 described herein may include or may be referred to as a base station 140 (e.g., a base transceiver station, a radio base station, an NR base station, an access point, a radio transceiver, a NodeB, an eNodeB (eNB), a next-generation NodeB or a giga-NodeB (either of which may be referred to as a gNB), a 5G NB, a next-generation eNB (ng-eNB), a Home NodeB, a Home eNodeB, or other suitable terminology). In some aspects, a network entity 105 (e.g., a base station 140) may be implemented in an aggregated (e.g., monolithic, standalone) base station architecture, which may be configured to utilize a protocol stack that is physically or logically integrated within a single network entity 105 (e.g., a single RAN node, such as a base station 140).

In some aspects, a network entity 105 may be implemented in a disaggregated architecture (e.g., a disaggregated base station architecture, a disaggregated RAN architecture), which may be configured to utilize a protocol stack that is physically or logically distributed among two or more network entities 105, such as an integrated access backhaul (IAB) network, an open RAN (O-RAN) (e.g., a network configuration sponsored by the O-RAN Alliance), or a virtualized RAN (vRAN) (e.g., a cloud RAN (C-RAN)). For example, a network entity 105 may include one or more of a central unit (CU) 160, a distributed unit (DU) 165, a radio unit (RU) 170, a RAN Intelligent Controller (RIC) 175 (e.g., a Near-Real Time RIC (Near-RT RIC), a Non-Real Time RIC (Non-RT RIC)), a Service Management and Orchestration (SMO) 180 system, or any combination thereof. An RU 170 may also be referred to as a radio head, a smart radio head, a remote radio head (RRH), a remote radio unit (RRU), or a transmission reception point (TRP). One or more components of the network entities 105 in a disaggregated RAN architecture may be co-located, or one or more components of the network entities 105 may be located in distributed locations (e.g., separate physical locations). In some aspects, one or more network entities 105 of a disaggregated RAN architecture may be implemented as virtual units (e.g., a virtual CU (VCU), a virtual DU (VDU), a virtual RU (VRU)).

The split of functionality between a CU 160, a DU 165, and an RU 170 is flexible and may support different functionalities depending on which functions (e.g., network layer functions, protocol layer functions, baseband functions, RF functions, and any combinations thereof) are performed at a CU 160, a DU 165, or an RU 170. For example, a functional split of a protocol stack may be employed between a CU 160 and a DU 165 such that the CU 160 may support one or more layers of the protocol stack and the DU 165 may support one or more different layers of the protocol stack. In some aspects, the CU 160 may host upper protocol layer (e.g., layer 3 (L3), layer 2 (L2)) functionality and signaling (e.g., RRC, service data adaption protocol (SDAP), Packet Data Convergence Protocol (PDCP)). The CU 160 may be connected to one or more DUs 165 or RUs 170, and the one or more DUs 165 or RUs 170 may host lower protocol layers, such as layer 1 (L1) (e.g., physical (PHY) layer) or L2 (e.g., RLC layer, medium access control (MAC) layer) functionality and signaling, and may each be at least partially controlled by the CU 160. Additionally, or alternatively, a functional split of the protocol stack may be employed between a DU 165 and an RU 170 such that the DU 165 may support one or more layers of the protocol stack and the RU 170 may support one or more different layers of the protocol stack. The DU 165 may support one or multiple different cells (e.g., via one or more RUs 170). In some cases, a functional split between a CU 160 and a DU 165, or between a DU 165 and an RU 170 may be within a protocol layer (e.g., some functions for a protocol layer may be performed by one of a CU 160, a DU 165, or an RU 170, while other functions of the protocol layer are performed by a different one of the CU 160, the DU 165, or the RU 170). A CU 160 may be functionally split further into CU control plane (CU-CP) and CU user plane (CU-UP) functions. A CU 160 may be connected to one or more DUs 165 via a midhaul communication link 162 (e.g., F1, F1-c, F1-u), and a DU 165 may be connected to one or more RUs 170 via a fronthaul communication link 168 (e.g., open fronthaul (FH) interface). In some aspects, a midhaul communication link 162 or a fronthaul communication link 168 may be implemented in accordance with an interface (e.g., a channel) between layers of a protocol stack supported by respective network entities 105 that are in communication via such communication links.

In wireless communications systems (e.g., wireless communications system 100), infrastructure and spectral resources for radio access may support wireless backhaul link capabilities to supplement wired backhaul connections, providing an IAB network architecture (e.g., to a core network 130). In some cases, in an IAB network, one or more network entities 105 (e.g., IAB nodes 104) may be partially controlled by each other. One or more IAB nodes 104 may be referred to as a donor entity or an IAB donor. One or more DUs 165 or one or more RUs 170 may be partially controlled by one or more CUs 160 associated with a donor network entity 105 (e.g., a donor base station 140). The one or more donor network entities 105 (e.g., IAB donors) may be in communication with one or more additional network entities 105 (e.g., IAB nodes 104) via supported access and backhaul links (e.g., backhaul communication links 120). IAB nodes 104 may include an IAB mobile termination (IAB-MT) controlled (e.g., scheduled) by DUs 165 of a coupled IAB donor. An IAB-MT may include an independent set of antennas for relay of communications with UEs 115, or may share the same antennas (e.g., of an RU 170) of an IAB node 104 used for access via the DU 165 of the IAB node 104 (e.g., referred to as virtual IAB-MT (vIAB-MT)). In some aspects, the IAB nodes 104 may include DUs 165 that support communication links with additional entities (e.g., IAB nodes 104, UEs 115) within the relay chain or configuration of the access network (e.g., downstream). In such cases, one or more components of the disaggregated RAN architecture (e.g., one or more IAB nodes 104 or components of IAB nodes 104) may be configured to operate according to the techniques described herein.

For instance, an access network (AN) or RAN may include communications between access nodes (e.g., an IAB donor), IAB nodes 104, and one or more UEs 115. The IAB donor may facilitate connection between the core network 130 and the AN (e.g., via a wired or wireless connection to the core network 130). That is, an IAB donor may refer to a RAN node with a wired or wireless connection to core network 130. The IAB donor may include a CU 160 and at least one DU 165 (e.g., and RU 170), in which case the CU 160 may communicate with the core network 130 via an interface (e.g., a backhaul link). IAB donor and IAB nodes 104 may communicate via an F1 interface according to a protocol that defines signaling messages (e.g., an F1 AP protocol). Additionally, or alternatively, the CU 160 may communicate with the core network via an interface, which may be an example of a portion of backhaul link, and may communicate with other CUs 160 (e.g., a CU 160 associated with an alternative IAB donor) via an Xn-C interface, which may be an example of a portion of a backhaul link.

An IAB node 104 may refer to a RAN node that provides IAB functionality (e.g., access for UEs 115, wireless self-backhauling capabilities). A DU 165 may act as a distributed scheduling node towards child nodes associated with the IAB node 104, and the LAB-MT may act as a scheduled node towards parent nodes associated with the IAB node 104. That is, an IAB donor may be referred to as a parent node in communication with one or more child nodes (e.g., an IAB donor may relay transmissions for UEs through one or more other IAB nodes 104). Additionally, or alternatively, an IAB node 104 may also be referred to as a parent node or a child node to other IAB nodes 104, depending on the relay chain or configuration of the AN. Therefore, the IAB-MT entity of IAB nodes 104 may provide a Uu interface for a child IAB node 104 to receive signaling from a parent IAB node 104, and the DU interface (e.g., DUs 165) may provide a Uu interface for a parent IAB node 104 to signal to a child IAB node 104 or UE 115.

For example, IAB node 104 may be referred to as a parent node that supports communications for a child IAB node, or referred to as a child IAB node associated with an IAB donor, or both. The IAB donor may include a CU 160 with a wired or wireless connection (e.g., a backhaul communication link 120) to the core network 130 and may act as parent node to IAB nodes 104. For example, the DU 165 of IAB donor may relay transmissions to UEs 115 through IAB nodes 104, or may directly signal transmissions to a UE 115, or both. The CU 160 of IAB donor may signal communication link establishment via an F1 interface to IAB nodes 104, and the IAB nodes 104 may schedule transmissions (e.g., transmissions to the UEs 115 relayed from the IAB donor) through the DUs 165. That is, data may be relayed to and from IAB nodes 104 via signaling via an NR Uu interface to MT of the IAB node 104. Communications with IAB node 104 may be scheduled by a DU 165 of IAB donor and communications with IAB node 104 may be scheduled by DU 165 of IAB node 104.

In the case of the techniques described herein applied in the context of a disaggregated RAN architecture, one or more components of the disaggregated RAN architecture may be configured to support information indications for Raptor codes as described herein. For example, some operations described as being performed by a UE 115 or a network entity 105 (e.g., a base station 140) may additionally, or alternatively, be performed by one or more components of the disaggregated RAN architecture (e.g., IAB nodes 104, DUs 165, CUs 160, RUs 170, RIC 175, SMO 180).

A UE 115 may include or may be referred to as a mobile device, a wireless device, a remote device, a handheld device, or a subscriber device, or some other suitable terminology, where the “device” may also be referred to as a unit, a station, a terminal, or a client, among other examples. A UE 115 may also include or may be referred to as a personal electronic device such as a cellular phone, a personal digital assistant (PDA), a tablet computer, a laptop computer, or a personal computer. In some aspects, a UE 115 may include or be referred to as a wireless local loop (WLL) station, an Internet of Things (IoT) device, an Internet of Everything (IoE) device, or a machine type communications (MTC) device, among other examples, which may be implemented in various objects such as appliances, or vehicles, meters, among other examples.

The UEs 115 described herein may be able to communicate with various types of devices, such as other UEs 115 that may sometimes act as relays as well as the network entities 105 and the network equipment including macro eNBs or gNBs, small cell eNBs or gNBs, or relay base stations, among other examples, as shown in FIG. 1.

The UEs 115 and the network entities 105 may wirelessly communicate with one another via one or more communication links 125 (e.g., an access link) using resources associated with one or more carriers. The term “carrier” may refer to a set of RF spectrum resources having a defined physical layer structure for supporting the communication links 125. For example, a carrier used for a communication link 125 may include a portion of a RF spectrum band (e.g., a bandwidth part (BWP)) that is operated according to one or more physical layer channels for a given radio access technology (e.g., LTE, LTE-A, LTE-A Pro, NR). Each physical layer channel may carry acquisition signaling (e.g., synchronization signals, system information), control signaling that coordinates operation for the carrier, user data, or other signaling. The wireless communications system 100 may support communication with a UE 115 using carrier aggregation or multi-carrier operation. A UE 115 may be configured with multiple downlink component carriers and one or more uplink component carriers according to a carrier aggregation configuration. Carrier aggregation may be used with both frequency division duplexing (FDD) and time division duplexing (TDD) component carriers. Communication between a network entity 105 and other devices may refer to communication between the devices and any portion (e.g., entity, sub-entity) of a network entity 105. For example, the terms “transmitting,” “receiving,” or “communicating,” when referring to a network entity 105, may refer to any portion of a network entity 105 (e.g., a base station 140, a CU 160, a DU 165, a RU 170) of a RAN communicating with another device (e.g., directly or via one or more other network entities 105).

In some aspects, such as in a carrier aggregation configuration, a carrier may also have acquisition signaling or control signaling that coordinates operations for other carriers. A carrier may be associated with a frequency channel (e.g., an evolved universal mobile telecommunication system terrestrial radio access (E-UTRA) absolute RF channel number (EARFCN)) and may be identified according to a channel raster for discovery by the UEs 115. A carrier may be operated in a standalone mode, in which case initial acquisition and connection may be conducted by the UEs 115 via the carrier, or the carrier may be operated in a non-standalone mode, in which case a connection is anchored using a different carrier (e.g., of the same or a different radio access technology).

The communication links 125 shown in the wireless communications system 100 may include downlink transmissions (e.g., forward link transmissions) from a network entity 105 to a UE 115, uplink transmissions (e.g., return link transmissions) from a UE 115 to a network entity 105, or both, among other configurations of transmissions. Carriers may carry downlink or uplink communications (e.g., in an FDD mode) or may be configured to carry downlink and uplink communications (e.g., in a TDD mode).

A carrier may be associated with a particular bandwidth of the RF spectrum and, in some aspects, the carrier bandwidth may be referred to as a “system bandwidth” of the carrier or the wireless communications system 100. For example, the carrier bandwidth may be one of a set of bandwidths for carriers of a particular radio access technology (e.g., 1.4, 3, 5, 10, 15, 20, 40, or 80 megahertz (MHz)). Devices of the wireless communications system 100 (e.g., the network entities 105, the UEs 115, or both) may have hardware configurations that support communications using a particular carrier bandwidth or may be configurable to support communications using one of a set of carrier bandwidths. In some aspects, the wireless communications system 100 may include network entities 105 or UEs 115 that support concurrent communications using carriers associated with multiple carrier bandwidths. In some aspects, each served UE 115 may be configured for operating using portions (e.g., a sub-band, a BWP) or all of a carrier bandwidth.

Signal waveforms transmitted via a carrier may be made up of multiple subcarriers (e.g., using multi-carrier modulation (MCM) techniques such as orthogonal frequency division multiplexing (OFDM) or discrete Fourier transform spread OFDM (DFT-S-OFDM)). In a system employing MCM techniques, a resource element may refer to resources of one symbol period (e.g., a duration of one modulation symbol) and one subcarrier, in which case the symbol period and subcarrier spacing may be inversely related. The quantity of bits carried by each resource element may depend on the modulation scheme (e.g., the order of the modulation scheme, the coding rate of the modulation scheme, or both), such that a relatively higher quantity of resource elements (e.g., in a transmission duration) and a relatively higher order of a modulation scheme may correspond to a relatively higher rate of communication. A wireless communications resource may refer to a combination of an RF spectrum resource, a time resource, and a spatial resource (e.g., a spatial layer, a beam), and the use of multiple spatial resources may increase the data rate or data integrity for communications with a UE 115.

The time intervals for the network entities 105 or the UEs 115 may be expressed in multiples of a basic time unit which may, for example, refer to a sampling period of Tₛ=1/(Δfₘₐₓ·N_{f}) seconds, for which Δfₘₐₓ may represent a supported subcarrier spacing, and N_{f} may represent a supported discrete Fourier transform (DFT) size. Time intervals of a communications resource may be organized according to radio frames each having a specified duration (e.g., 10 milliseconds (ms)). Each radio frame may be identified by a system frame number (SFN) (e.g., ranging from 0 to 1023).

Each frame may include multiple consecutively-numbered subframes or slots, and each subframe or slot may have the same duration. In some aspects, a frame may be divided (e.g., in the time domain) into subframes, and each subframe may be further divided into a quantity of slots. Alternatively, each frame may include a variable quantity of slots, and the quantity of slots may depend on subcarrier spacing. Each slot may include a quantity of symbol periods (e.g., depending on the length of the cyclic prefix prepended to each symbol period). In some wireless communications systems 100, a slot may further be divided into multiple mini-slots associated with one or more symbols. Excluding the cyclic prefix, each symbol period may be associated with one or more (e.g., N_{f}) sampling periods. The duration of a symbol period may depend on the subcarrier spacing or frequency band of operation.

A subframe, a slot, a mini-slot, or a symbol may be the smallest scheduling unit (e.g., in the time domain) of the wireless communications system 100 and may be referred to as a transmission time interval (TTI). In some aspects, the TTI duration (e.g., a quantity of symbol periods in a TTI) may be variable. Additionally, or alternatively, the smallest scheduling unit of the wireless communications system 100 may be dynamically selected (e.g., in bursts of shortened TTIs (STTIs)).

Physical channels may be multiplexed for communication using a carrier according to various techniques. A physical control channel and a physical data channel may be multiplexed for signaling via a downlink carrier, for example, using one or more of time division multiplexing (TDM) techniques, frequency division multiplexing (FDM) techniques, or hybrid TDM-FDM techniques. A control region (e.g., a control resource set (CORESET)) for a physical control channel may be defined by a set of symbol periods and may extend across the system bandwidth or a subset of the system bandwidth of the carrier. One or more control regions (e.g., CORESETs) may be configured for a set of the UEs 115. For example, one or more of the UEs 115 may monitor or search control regions for control information according to one or more search space sets, and each search space set may include one or multiple control channel candidates in one or more aggregation levels arranged in a cascaded manner. An aggregation level for a control channel candidate may refer to an amount of control channel resources (e.g., control channel elements (CCEs)) associated with encoded information for a control information format having a given payload size. Search space sets may include common search space sets configured for sending control information to multiple UEs 115 and UE-specific search space sets for sending control information to a specific UE 115.

A network entity 105 may provide communication coverage via one or more cells, for example a macro cell, a small cell, a hot spot, or other types of cells, or any combination thereof. The term “cell” may refer to a logical communication entity used for communication with a network entity 105 (e.g., using a carrier) and may be associated with an identifier for distinguishing neighboring cells (e.g., a physical cell identifier (PCID), a virtual cell identifier (VCID), or others). In some aspects, a cell also may refer to a coverage area 110 or a portion of a coverage area 110 (e.g., a sector) over which the logical communication entity operates. Such cells may range from smaller areas (e.g., a structure, a subset of structure) to larger areas depending on various factors such as the capabilities of the network entity 105. For example, a cell may be or include a building, a subset of a building, or exterior spaces between or overlapping with coverage areas 110, among other examples.

A macro cell generally covers a relatively large geographic area (e.g., several kilometers in radius) and may allow unrestricted access by the UEs 115 with service subscriptions with the network provider supporting the macro cell. A small cell may be associated with a lower-powered network entity 105 (e.g., a lower-powered base station 140), as compared with a macro cell, and a small cell may operate using the same or different (e.g., licensed, unlicensed) frequency bands as macro cells. Small cells may provide unrestricted access to the UEs 115 with service subscriptions with the network provider or may provide restricted access to the UEs 115 having an association with the small cell (e.g., the UEs 115 in a closed subscriber group (CSG), the UEs 115 associated with users in a home or office). A network entity 105 may support one or multiple cells and may also support communications via the one or more cells using one or multiple component carriers.

In some aspects, a network entity 105 (e.g., a base station 140, an RU 170) may be movable and therefore provide communication coverage for a moving coverage area 110. In some aspects, different coverage areas 110 associated with different technologies may overlap, but the different coverage areas 110 may be supported by the same network entity 105. In some other examples, the overlapping coverage areas 110 associated with different technologies may be supported by different network entities 105. The wireless communications system 100 may include, for example, a heterogeneous network in which different types of the network entities 105 provide coverage for various coverage areas 110 using the same or different radio access technologies.

The wireless communications system 100 may support synchronous or asynchronous operation. For synchronous operation, network entities 105 (e.g., base stations 140) may have similar frame timings, and transmissions from different network entities 105 may be approximately aligned in time. For asynchronous operation, network entities 105 may have different frame timings, and transmissions from different network entities 105 may, in some aspects, not be aligned in time. The techniques described herein may be used for either synchronous or asynchronous operations.

The wireless communications system 100 may be configured to support ultra-reliable communications or low-latency communications, or various combinations thereof. For example, the wireless communications system 100 may be configured to support ultra-reliable low-latency communications (URLLC). The UEs 115 may be designed to support ultra-reliable, low-latency, or critical functions. Ultra-reliable communications may include private communication or group communication and may be supported by one or more services such as push-to-talk, video, or data. Support for ultra-reliable, low-latency functions may include prioritization of services, and such services may be used for public safety or general commercial applications. The terms ultra-reliable, low-latency, and ultra-reliable low-latency may be used interchangeably herein.

In some aspects, a UE 115 may be configured to support communicating directly with other UEs 115 via a device-to-device (D2D) communication link 135 (e.g., in accordance with a peer-to-peer (P2P), D2D, or sidelink protocol). In some aspects, one or more UEs 115 of a group that are performing D2D communications may be within the coverage area 110 of a network entity 105 (e.g., a base station 140, an RU 170), which may support aspects of such D2D communications being configured by (e.g., scheduled by) the network entity 105. In some aspects, one or more UEs 115 of such a group may be outside the coverage area 110 of a network entity 105 or may be otherwise unable to or not configured to receive transmissions from a network entity 105. In some aspects, groups of the UEs 115 communicating via D2D communications may support a one-to-many (1:M) system in which each UE 115 transmits to each of the other UEs 115 in the group. In some aspects, a network entity 105 may facilitate the scheduling of resources for D2D communications. In some other examples, D2D communications may be carried out between the UEs 115 without an involvement of a network entity 105.

The core network 130 may provide user authentication, access authorization, tracking, Internet Protocol (IP) connectivity, and other access, routing, or mobility functions. The core network 130 may be an evolved packet core (EPC) or 5G core (5GC), which may include at least one control plane entity that manages access and mobility (e.g., a mobility management entity (MME), an access and mobility management function (AMF)) and at least one user plane entity that routes packets or interconnects to external networks (e.g., a serving gateway (S-GW), a Packet Data Network (PDN) gateway (P-GW), or a user plane function (UPF)). The control plane entity may manage non-access stratum (NAS) functions such as mobility, authentication, and bearer management for the UEs 115 served by the network entities 105 (e.g., base stations 140) associated with the core network 130. User IP packets may be transferred through the user plane entity, which may provide IP address allocation as well as other functions. The user plane entity may be connected to IP services 150 for one or more network operators. The IP services 150 may include access to the Internet, Intranet(s), an IP Multimedia Subsystem (IMS), or a Packet-Switched Streaming Service.

The wireless communications system 100 may operate using one or more frequency bands, which may be in the range of 300 megahertz (MHz) to 300 gigahertz (GHz). Generally, the region from 300 MHz to 3 GHz is known as the ultra-high frequency (UHF) region or decimeter band because the wavelengths range from approximately one decimeter to one meter in length. UHF waves may be blocked or redirected by buildings and environmental features, which may be referred to as clusters, but the waves may penetrate structures sufficiently for a macro cell to provide service to the UEs 115 located indoors. Communications using UHF waves may be associated with smaller antennas and shorter ranges (e.g., less than 100 kilometers) compared to communications using the smaller frequencies and longer waves of the high frequency (HF) or very high frequency (VHF) portion of the spectrum below 300 MHz.

The wireless communications system 100 may utilize both licensed and unlicensed RF spectrum bands. For example, the wireless communications system 100 may employ License Assisted Access (LAA), LTE-Unlicensed (LTE-U) radio access technology, or NR technology using an unlicensed band such as the 5 GHz industrial, scientific, and medical (ISM) band. While operating using unlicensed RF spectrum bands, devices such as the network entities 105 and the UEs 115 may employ carrier sensing for collision detection and avoidance. In some aspects, operations using unlicensed bands may be based on a carrier aggregation configuration in conjunction with component carriers operating using a licensed band (e.g., LAA). Operations using unlicensed spectrum may include downlink transmissions, uplink transmissions, P2P transmissions, or D2D transmissions, among other examples.

A network entity 105 (e.g., a base station 140, an RU 170) or a UE 115 may be equipped with multiple antennas, which may be used to employ techniques such as transmit diversity, receive diversity, multiple-input multiple-output (MIMO) communications, or beamforming. The antennas of a network entity 105 or a UE 115 may be located within one or more antenna arrays or antenna panels, which may support MIMO operations or transmit or receive beamforming. For example, one or more base station antennas or antenna arrays may be co-located at an antenna assembly, such as an antenna tower. In some aspects, antennas or antenna arrays associated with a network entity 105 may be located at diverse geographic locations. A network entity 105 may include an antenna array with a set of rows and columns of antenna ports that the network entity 105 may use to support beamforming of communications with a UE 115. Likewise, a UE 115 may include one or more antenna arrays that may support various MIMO or beamforming operations. Additionally, or alternatively, an antenna panel may support RF beamforming for a signal transmitted via an antenna port.

Beamforming, which may also be referred to as spatial filtering, directional transmission, or directional reception, is a signal processing technique that may be used at a transmitting device or a receiving device (e.g., a network entity 105, a UE 115) to shape or steer an antenna beam (e.g., a transmit beam, a receive beam) along a spatial path between the transmitting device and the receiving device. Beamforming may be achieved by combining the signals communicated via antenna elements of an antenna array such that some signals propagating along particular orientations with respect to an antenna array experience constructive interference while others experience destructive interference. The adjustment of signals communicated via the antenna elements may include a transmitting device or a receiving device applying amplitude offsets, phase offsets, or both to signals carried via the antenna elements associated with the device. The adjustments associated with each of the antenna elements may be defined by a beamforming weight set associated with a particular orientation (e.g., with respect to the antenna array of the transmitting device or receiving device, or with respect to some other orientation).

A network entity 105 or a UE 115 may use beam sweeping techniques as part of beamforming operations. For example, a network entity 105 (e.g., a base station 140, an RU 170) may use multiple antennas or antenna arrays (e.g., antenna panels) to conduct beamforming operations for directional communications with a UE 115. Some signals (e.g., synchronization signals, reference signals, beam selection signals, or other control signals) may be transmitted by a network entity 105 multiple times along different directions. For example, the network entity 105 may transmit a signal according to different beamforming weight sets associated with different directions of transmission. Transmissions along different beam directions may be used to identify (e.g., by a transmitting device, such as a network entity 105, or by a receiving device, such as a UE 115) a beam direction for later transmission or reception by the network entity 105.

Some signals, such as data signals associated with a particular receiving device, may be transmitted by transmitting device (e.g., a transmitting network entity 105, a transmitting UE 115) along a single beam direction (e.g., a direction associated with the receiving device, such as a receiving network entity 105 or a receiving UE 115). In some aspects, the beam direction associated with transmissions along a single beam direction may be determined based on a signal that was transmitted along one or more beam directions. For example, a UE 115 may receive one or more of the signals transmitted by the network entity 105 along different directions and may report to the network entity 105 an indication of the signal that the UE 115 received with a highest signal quality or an otherwise acceptable signal quality.

In some aspects, transmissions by a device (e.g., by a network entity 105 or a UE 115) may be performed using multiple beam directions, and the device may use a combination of digital precoding or beamforming to generate a combined beam for transmission (e.g., from a network entity 105 to a UE 115). The UE 115 may report feedback that indicates precoding weights for one or more beam directions, and the feedback may correspond to a configured set of beams across a system bandwidth or one or more sub-bands. The network entity 105 may transmit a reference signal (e.g., a cell-specific reference signal (CRS), a channel state information reference signal (CSI-RS)), which may be precoded or unprecoded. The UE 115 may provide feedback for beam selection, which may be a precoding matrix indicator (PMI) or codebook-based feedback (e.g., a multi-panel type codebook, a linear combination type codebook, a port selection type codebook). Although these techniques are described with reference to signals transmitted along one or more directions by a network entity 105 (e.g., a base station 140, an RU 170), a UE 115 may employ similar techniques for transmitting signals multiple times along different directions (e.g., for identifying a beam direction for subsequent transmission or reception by the UE 115) or for transmitting a signal along a single direction (e.g., for transmitting data to a receiving device).

A receiving device (e.g., a UE 115) may perform reception operations in accordance with multiple receive configurations (e.g., directional listening) when receiving various signals from a receiving device (e.g., a network entity 105), such as synchronization signals, reference signals, beam selection signals, or other control signals. For example, a receiving device may perform reception in accordance with multiple receive directions by receiving via different antenna subarrays, by processing received signals according to different antenna subarrays, by receiving according to different receive beamforming weight sets (e.g., different directional listening weight sets) applied to signals received at multiple antenna elements of an antenna array, or by processing received signals according to different receive beamforming weight sets applied to signals received at multiple antenna elements of an antenna array, any of which may be referred to as “listening” according to different receive configurations or receive directions. In some aspects, a receiving device may use a single receive configuration to receive along a single beam direction (e.g., when receiving a data signal). The single receive configuration may be aligned along a beam direction determined based on listening according to different receive configuration directions (e.g., a beam direction determined to have a highest signal strength, highest signal-to-noise ratio (SNR), or otherwise acceptable signal quality based on listening according to multiple beam directions).

The wireless communications system 100 may be a packet-based network that operates according to a layered protocol stack. In the user plane, communications at the bearer or PDCP layer may be IP-based. An RLC layer may perform packet segmentation and reassembly to communicate via logical channels. A MAC layer may perform priority handling and multiplexing of logical channels into transport channels. The MAC layer also may implement error detection techniques, error correction techniques, or both to support retransmissions to improve link efficiency. In the control plane, an RRC layer may provide establishment, configuration, and maintenance of an RRC connection between a UE 115 and a network entity 105 or a core network 130 supporting radio bearers for user plane data. A PHY layer may map transport channels to physical channels.

The UEs 115 and the network entities 105 may support retransmissions of data to increase the likelihood that data is received successfully. Hybrid automatic repeat request (HARQ) feedback is one technique for increasing the likelihood that data is received correctly via a communication link (e.g., a communication link 125, a D2D communication link 135). HARQ may include a combination of error detection (e.g., using a cyclic redundancy check (CRC)), forward error correction (FEC), and retransmission (e.g., automatic repeat request (ARQ)). HARQ may improve throughput at the MAC layer in poor radio conditions (e.g., low signal-to-noise conditions). In some aspects, a device may support same-slot HARQ feedback, in which case the device may provide HARQ feedback in a specific slot for data received via a previous symbol in the slot. In some other examples, the device may provide HARQ feedback in a subsequent slot, or according to some other time interval.

Wireless communications systems are widely deployed to provide various types of communication content such as voice, video, packet data, messaging, broadcast, and so on. These systems may be multiple-access systems capable of supporting communication with multiple users by sharing the available system resources (e.g., time, frequency, and power). A wireless network, for example a wireless local area network (WLAN), such as a Wi-Fi (i.e., Institute of Electrical and Electronics Engineers (IEEE) 802.11) network may include an access point (AP) that may communicate with one or more wireless or mobile devices. The AP may be coupled to a network, such as the Internet, and may enable a mobile device to communicate via the network (or communicate with other devices coupled to the access point). A wireless device may communicate with a network device bi-directionally. For example, in a WLAN, a device may communicate with an associated AP via downlink (e.g., the communication link from the AP to the device) and uplink (e.g., the communication link from the device to the AP). A wireless personal area network (PAN), which may include a Bluetooth connection, may provide for short range wireless connections between two or more paired wireless devices. For example, wireless devices such as cellular phones may utilize wireless PAN communications to exchange information such as audio signals with wireless headsets.

In some cases, an encoding device (e.g., a UE 115 or network entity 105) may perform fountain encoding. Fountain codes, which may also be referred to as network codes based on being applied in a network layer, may be rateless codes whose generator matrix may have unlimited columns. Performing fountain coding may involve the encoding device dividing a RLC service data unit (SDU) into K data blocks s₁, . . . , s_{K}, where each of the data blocks may contain a same number of bits. The encoding device may then encode the K data blocks into Z packets p₁, . . . , p_{z} using a mother generator matrix. For instance, the encoding device may determine each of the Z packets as

$${p}_{z} = {\sum }_{k = 1}^{K} {s}_{k} {H}_{kz} ,$$

where H_{kz} may represent a value of an entry at a kth row and an zth column of the mother generator matrix H. Each of the Z packets may correspond to a different column of the mother generator matrix.

When a decoding device receives the fountain encoded transmission from the encoding device, the decoding device may receive at least some of the Z packets (e.g., Q, where Q≤Z). Assuming that the number of Q packets successfully received is greater than a threshold amount (e.g., greater than K), the decoding device may construct an invertible generator matrix G from the Q packets. For instance, the decoding device may identify a header for a first of the packets and may identify, from the header, a column of the mother generator matrix H. The decoding device may perform this identification and may construct the invertible generator matrix by mapping each of the identified columns of the mother generator matrix H to a column of the invertible generator matrix G.

Once the decoding device generates the invertible generator matrix G, the decoding device may reconstruct the K data blocks based on the invertible generator matrix G. For instance, if each of the K recovered data blocks are denoted by cₖ, where 0<k≤K, and each of the packets is denoted by p_{q}, where 0<q≤Q, then cₖ may be equal to

$${\sum }_{q = 1}^{Q} {p}_{q} {G}_{qk}^{- 1} ,$$

where

$${G}_{qk}^{- 1}$$

may represent a qth row and a kth column of the inverted generator matrix G⁻¹. Generally, the data blocks may be recovered if generator matrix G according to the Q data blocks is invertible or if the rank of invertible generator matrix G is K. For conventional ARQ, the original generator matrix may start with a unit matrix.

One type of fountain coding is Luby transform (LT) coding. Performing LT encoding may involve randomly choosing a degree dᵢ from a degree distribution and randomly choosing dᵢ distinct source symbols, which may be a type of data block, with uniform distribution and combining them (e.g., performing one or more exclusive/or (XOR) operations). LT decoding (e.g., belief-propagation (BP) decoding) may involve first finding an encoded symbol tⱼ connected to one source symbol sᵢ (e.g., an encoded symbol whose degree is one). Then the decoding device may set sᵢ to equal tⱼ; may XOR sᵢ to each encoded symbols connected to sᵢ; and may remove each edge connected to source symbol sᵢ. Such a procedure may continue until sᵢ is determined for each value of i. If there is no encoded symbol connected to only one source symbol sᵢ_{ₒ}, the decoding process may fail for that iₒ value. Alternatively, a decoding device may perform a gaussian elimination process (GE) to decode the encoded symbols.

Raptor coding may be an enhancement of LT coding. For instance, performing Raptor coding may be similar to performing a low-density parity check (LDPC) and LT coding where a number of degrees is below or equal to a threshold amount (e.g., less than or equal to 3). A Raptor code may be applied for multimedia broadcast multicast service (MBMS). Additionally, or alternatively, network codes, which may include Raptor codes, may be used for IAB.

In some aspects, a decoding device (e.g., a UE 115 or a network entity 105) may receive a set of packets from an encoding device (e.g., a network entity 105 or a UE 115). A header for each of the packets may include an SBN and an ESI for each encoded symbol. The SBN may be an integer identifier (e.g., a first 16 bits of a header) for the source block that the encoded symbols within the packet relate to and the ESI may be an integer identifier (e.g., the last 16 bits of the header) for the encoded symbols within the packet. Each packet may also include one or more encoded symbols. Based on the SBN and ESI, an encoding device and/or a decoding device may determine which source symbols are selected to generate the encoded symbol. In some aspects, an encoding device may perform triple generation based on the ESI. For instance, the encoding device may determine (d, a, b)=Trip (K, X), where K is a number of source symbols and X is an ESI value. Generally, d may equal Deg[v], v may be equal to Rand [Y, 0, 2²⁰], Y may be equal to (B+X*A) % Q, and Q may be equal to the largest prime number smaller than 2^{M}, where M may be the size in bits of Kor X and % is the modulus operator. In the example where M=16, A may be equal to (53591+J(K)*997) % Q and B may be equal to 10267*(J(K)*997) % Q, where J(K) may be a systematic index associated with K. Additionally, a may equal 1+Rand[Y, 1, L′−1] and b may equal Rand [Y, 2, L′], where L′ may equal the smallest prime greater than or equal to L and where L=K+S+H, where S may correspond to a number of LDPC symbols and H may correspond to a number of half symbols.

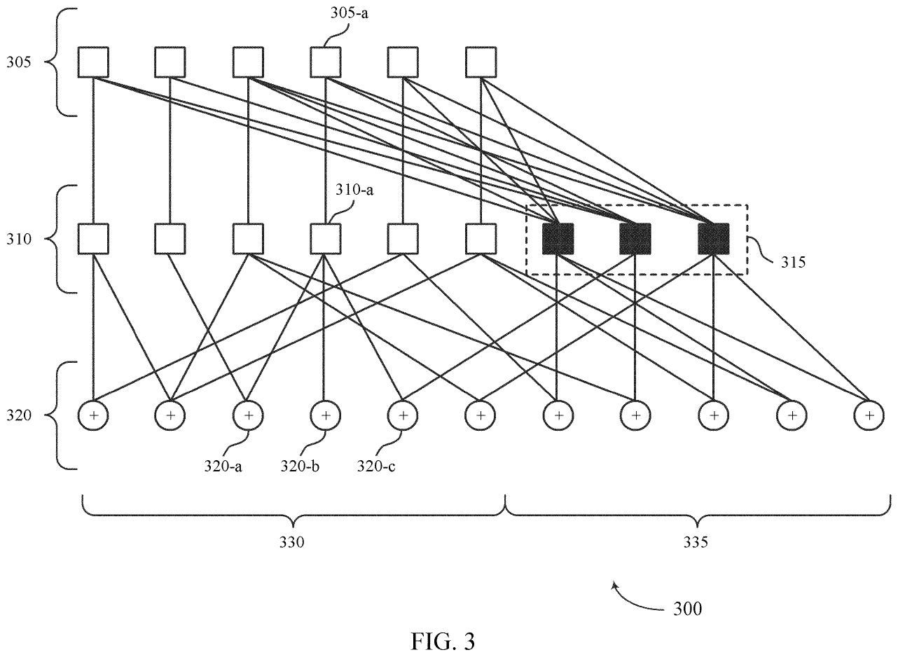

The encoding device may perform LT encoded symbol generation based on the triple generation. For instance, the encoding device may determine P encoded symbols according to LTEnc(K, C[0], C[1], . . . , C[L−1], (d, a, b)). For instance, the decoding device, while b≥L, may determine b=(b+a) % L′ until b<L, where the result may be C[b]. Then for j=1, . . . , min (d−1, L−1), the decoding device may determine b=(b+a) % L. Then, while b≥L, the decoding device may determine b=(b+a) % L′ until b<L. Then the decoding device may determine that result=result^{C[b]}. The result may then be returned. Additional details about encoded symbols may be described with reference to FIG. 3.

In some aspects, Raptor codes may be used as an erasure-correction code (e.g., in the application layer). In such examples, each encoded symbol may be either decoded correctly or discarded. As such, SBN and ESI may be added as a header file to the encoded symbols. However, when Raptor codes are used at the RLC or PHY layer, using SBN and ESI as a header file to the encoded symbols may be disadvantageous. For instance, in cases where the decoding device is unable to decode encoded symbols correctly, the decoding device may not have access to the SBN and ESI information. As such, the decoding device may lose soft information of each of the encoded symbols and may not be capable of determining which source symbols are selected to generate the encoded symbol. In such cases, the decoding device may not be capable of performing soft-combining, where soft-combining refers to a procedure by which the decoding device may combine a code block of a first redundancy version with a second code block of a second redundancy version to aid in decoding.

According to various aspects described herein, the encoding device and the decoding device may communicate the ESI(s) and SBN separately from the encoded symbols. For example, the indications of the SBN and/or ESI(s) may be transmitted using either an unused or repurposed field in the DCI that schedules a transmission that includes the encoded symbols or in a new DCI that piggybacks on a downlink shared channel transmission that includes the encoded symbols. Additionally, or alternatively, in a first option, the ESI(s) may be explicitly indicated by the DCI. In another option, the network entity 105 may indicate a configuration (e.g., via RRC messaging) for implicitly determining the ESI based on information conveyed in the DCI. The configuration message may include parameters to allow a receiving device to determine the ESIs from scheduling information (e.g., a position of resource blocks or an SFN) or via a DCI sequence. For example, the UE 115 may receive the scheduling information and may generate ESIs based on a function of the scheduling information.

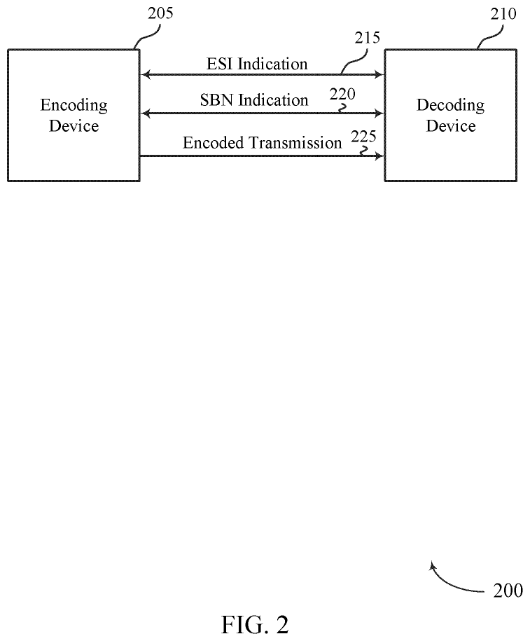

FIG. 2 illustrates an example of a wireless communications system 200 that supports information indications for Raptor codes in accordance with one or more aspects of the present disclosure. In some aspects, wireless communications system 200 may implement aspects of wireless communications system 100. For instance, encoding device 205 and decoding device 210 may each be examples of a UE 115 or network entity 105 as described with reference to FIG. 1.

At an initial time, an encoding device 205 may have a set of source symbols to indicate to a decoding device 210. Generally, each data of length n bits may be partitioned into K=n/l input symbols (e.g., source symbols) such that each input symbol may contain l bits. The encoding device 205 may use these K symbols to generate encoded symbols. To generate each encoded symbol, the encoding device 205 may encode the set of source symbols with a rateless code. For example, if performing Raptor coding, the encoding device 205 may select a degree dᵢ from a degree distribution; may select at least one of the source symbols according to the identified degree; and may generate the encoded symbol based on the selected at least one of the source symbols. More details about Raptor coding may be described elsewhere herein, for example, with reference to FIG. 3.

Each of the set of encoded symbols may have an associated ESI and SBN. To communicate the ESI, the encoding device 205 may communicate an ESI indication 215 (e.g., an indication of a set of ESIs) with decoding device 210 via a control channel, for example via a DCI as described herein.

Whether the encoding device 205 or the decoding device 210 provides the ESI indication 215 may be based on a type of communications to be performed between the encoding device 205 and the decoding device 210. For instance, for uplink communications, the decoding device 210 may transmit the ESI indication 215 to the encoding device 205. For downlink communications, the encoding device 205 may transmit the ESI indication 215 to the decoding device 210. For sidelink communications, the encoding device 205 or the decoding device 210 may transmit the ESI indication 215.

To communicate the SBN, the encoding device 205 may communicate an SBN indication 220 (e.g., an indication of the SNB) with decoding device 210 via a control channel, for example in a repurposed field in the DCI that schedules transmission of the encoded symbols or in a DCI that piggybacks on the downlink shared channel transmission that includes the encoded symbols. As another example, the SBN indication 220 may be transmitted via a MAC control element (MAC-CE) that schedules transmission of the encoded symbols.

Whether the encoding device 205 or the decoding device 210 provides the SBN indication 220 may be based on a type of communications to be performed between the encoding device 205 and the decoding device 210. For instance, for uplink communications, the decoding device 210 may transmit the SBN indication 220 to the encoding device 205. For downlink communications, the encoding device 205 may transmit the SBN indication 220 to the decoding device 210. For sidelink communications, the encoding device 205 or the decoding device 210 may transmit the SBN indication 220.

The encoding device 205 may transmit an encoded transmission 225 to decoding device 210 via a data channel. In some aspects, prior to transmitting the encoded transmission 225 and in cases where the encoded transmission 225 is for downlink communications, the encoding device 205 may schedule a downlink data channel (e.g., a physical downlink shared channel (PDSCH)); generate ESI based on scheduling information; and may perform triple generation and LT encoded symbol generation (e.g., as described in FIG. 1) using the ESI to generate a set of encoded symbols. The encoded transmission 225 may include a first transport block (TB) which may be dividable or partitionable into K first code blocks (CBs) with channel coding (e.g., where K is a positive integer, such as 6). Each first CB may include a respective set of packets and each set of packets may include one or more of the set of encoded symbols. In examples where the scheduling information provides the ESI indication 215, the scheduling information may point to resources that the decoding device 210 may use to receive the encoded transmission 225 and/or that the encoding device 205 may use to transmit the encoded transmission 225. The encoded transmission 225 may exclude any indication of the set of ESIs, the SBN, or both based on the encoding device 205 communicating the ESI indication 215, the SBN indication 220, or both, respectively, with the decoding device 210. In cases where the decoding device 210 determines ESI from scheduling information, the encoded symbols may be transmitted at least partially out of order, but may be transmitted based on calculated ESI (e.g., based on a result of f (scheduling information)).

The decoding device 210 may receive the encoded transmission 225 and may decode the one or more encoded symbols of each set of packets, which may be referred to as a set of encoded symbols. In some aspects, the decoding device 210 may decode the set of encoded symbols based on the set of ESIs, the SBN, or both. For example, the decoding device 210 may perform the decoding according to a Raptor code on the set of encoded symbols to generate a set of source symbols. In some aspects where the encoded transmission 225 is a downlink transmission, the decoding device 210 may generate ESI based on received scheduling information.

After receiving the encoded transmission 225, decoding device 210 may provide feedback to the encoding device 205. The type of feedback that the decoding device 210 provides may depend on whether the decoding device successfully recovered the set of source symbols. For instance, if the decoding device 210 has successfully recovered each source symbol in the set of source symbols (e.g., the decoding device 210 has successfully decoded each CB in the TB), the decoding device 210 may transmit an acknowledgment message (e.g., an acknowledgment (ACK)) to the encoding device 205. Alternatively, if the decoding device 210 has failed to successfully recover each source symbol in the set of source symbols (e.g., the decoding device 210 has failed to successfully decode at least one first CB in the first TB), the decoding device 210 may transmit a number of first CBs that the decoding device 210 has failed to decode (e.g., negative acknowledgment (NACK) first CBs or NACKed first CBs).

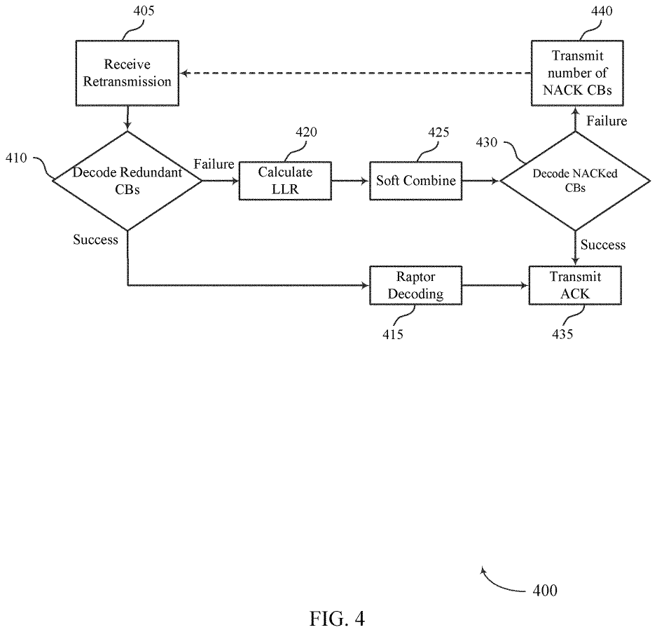

If the decoding device 210 provides a number of NACKed first CBs to the encoding device 205, encoding device 205 may provide a retransmission. The retransmission may include a second TB including L=K+N second CBs, where N refers to a number of redundant second CBs. Redundant second CBs may be second CBs that are constructed using multiple first CBs. The K first CBs of the encoded transmission 225 may be associated with a first redundancy version (RV) and the K non-redundant second CBs of the retransmission may be associated with a second RV. For example, if the K first CBs of the encoded transmission 225 are associated with RV1, the K non-redundant second CBs of the retransmission may be associated with RV2. In a circular buffer, the encoding device 205 may transmit CB_i with RV1, RV2, RV3, and so on. The encoding device 205 may regard the K non-redundant second CBs as source symbols of a systematic Raptor code and may generate associated encoded symbols (e.g., the N redundant second CBs) for retransmission. If the decoding device 210 fails to decode the N redundant second CBs, the decoding device 210 may perform a decoding process that utilizes soft-combining, where performing the soft-combining may be based on the ESI. Additional details about this procedure may be described with reference to FIG. 4. SBN, in some cases, may not change in each HARQ process. As such, the SBN indication 220 transmitted for encoded transmission 225 may not be retransmitted for the retransmission.

The techniques as described herein may have one or more advantages. For instance, even if encoded symbols encoded according to a Raptor code are not decoded correctly, the decoding device 210 may still be able to determine which source symbols were selected to generate the encoded symbols. Additionally, the decoding device 210 may be able to perform soft-combining, which may provide the decoding device 210 with soft information of NACK-encoded symbols and may, accordingly, aid in the decoding of source symbols.

FIG. 3 illustrates an example of a Raptor encoding scheme 300 that supports information indications for Raptor codes in accordance with one or more aspects of the present disclosure. In some aspects, Raptor encoding scheme 300 may be implemented by aspects of wireless communications system 100. For instance, Raptor encoding scheme 300 may be an example of a scheme by which an encoding device 205 may encode source symbols.

Initially, an encoding device 205 may have a set of source symbols 305. As part of a pre-coding process, encoding device 205 may generate intermediate symbols 310. Generating intermediate symbols 310 may involve mapping each source symbol 305 to a unique intermediate symbol 310. For instance, source symbol 305-a may map to intermediate symbol 310-a. Additionally, generating intermediate symbols may involve mapping multiple source symbols 305 to each of a set of redundant intermediate symbols 315, which may also be referred to as redundant nodes. The redundant intermediate symbols 315 may include S low-density parity check (LDPC) symbols (e.g., where each source symbol 305 may appear three times over the S LDPC symbols). Additionally, or alternatively, the redundant intermediate symbols 315 may include H half symbols (e.g., where each encoded symbol 320 may include ceiling (H/2) source symbols 305). The redundant intermediate symbols 315 may be based on the other intermediate symbols 310 (e.g., the first M intermediate symbols 310). The source symbols as described in FIG. 2 may correspond to source symbols 305 or intermediate symbols 310.

As part of an LT coding process, the encoding device 205 may generate encoded symbols 320. Generating the encoded symbols may involve choosing a degree dᵢ from a degree distribution; choosing or selecting dᵢ distinct intermediate symbols 310 according to a uniform distribution; and combining them (e.g., performing one or more XORs). Using a uniform distribution may ensure that each intermediate symbol 310 is selected approximately a same amount. In one example, the encoding device 205 may identify a degree of two; may select intermediate symbol 310-a and another intermediate symbol 310; and may combine (e.g., XOR) them to generate encoded symbol 320-a. In another example, encoding device 205 may identify a degree of one; may select intermediate symbol 310-a and may use intermediate symbol 310-a as encoded symbol 320-b. In another example, the encoding device 205 may identify a degree of three; may select intermediate symbol 310-a and two other intermediate symbols 310; and may combine (e.g., XOR) them to generate encoded symbol 320-c. Some of the encoded symbols 320 may be referred to as systematic symbols 330 and other of the encoded symbols 320 may be referred to as repair symbols 335.

Performing the procedure described herein may reduce the encoding and decoding complexities of LT codes by reducing the average degree. In such cases, an encoding device 205 may perform Raptor coding as described herein, which may use LDPC and an LT code (e.g., a weak LT code) with an average degree that is below or at a threshold amount (e.g., 3).

FIG. 4 illustrates an example of a decoding scheme 400 that supports information indications for Raptor codes in accordance with one or more aspects of the present disclosure. In some aspects, decoding scheme 400 may be implemented by aspects of wireless communications system 100. For example, the decoding scheme 400 may be an example of a procedure by which a decoding device 210 may decode code blocks of a transmission or retransmission.

As described herein, a decoding device 210 may receive an encoded transmission (e.g., an encoded transmission 225), where the encoded transmission includes a first TB partitionable into a set of first CBs (e.g., 6 first CBs: CB1, CB2, CB3, CB4, CB5, and CB6 with an RV of RV0). The decoding device 210 may perform Raptor decoding on the set of first CBs and may successfully decode a first subset (e.g., CB1, CB3, CB4, and CB5) and may fail to decode a second subset (e.g., CB2 and CB6). As such, the decoding device 210 may provide HARQ feedback to the encoding device 205. For instance, the decoding device 210 may indicate a number of first CBs in the second subset (e.g., 2).

Accordingly, encoding device 205 may transmit a retransmission that includes a second TB partitionable into a set of second CBs (e.g., 2 second CBs: CB7, and CB8 with an RV of RV1). Some of the second CBs may be associated with multiple second CBs. For instance, CB7 may be generated by XORing CB2 with CB4 and CB8 may be generated by XORing CB3 with CB5 and CB6.

At 405, the decoding device 210 may receive the retransmission. At 410, the decoding device 210 may perform a first level of decoding (e.g., packet CRC or checksum) to attempt to verify the encoded bits of the redundant second CBs (e.g., CB7 and CB8). If the decoding device 210 successfully receives the encoded bits of the redundant second CBs, the decoding device 210, at 415, may perform Raptor decoding on the second subset that the decoding device 210 failed to decode previously (e.g., CB2 and CB6 with RV1).

Alternatively, if the decoding device 210 fails to successfully verify that the encoded bits of the redundant second CB were received correctly, the decoding device 210 may, at 420, calculate log-likelihood ratio (LLR) for the second subset that the decoding device 210 failed to decode previously. For instance, the decoding device 210 may determine an LLR for CB2 with RV1 as LLR (CB7)*sign (CB4) and may determine an LLR for CB6 with RV1 as LLR (CB8)*sign (CB3)*sign (CB5). At 425, the decoding device 210 may perform a soft-combining procedure based on the ESI. For instance, the decoding device 210 may combine CB2 of RV1 with CB2 of RV0 and may combine CB6 of RV1 with CB6 of RV0.

At 430, the decoding device 210 may attempt to successfully decode the soft-combined second CBs. If the decoding device 210 succeeds and/or in cases where the Raptor decoding at 415 is performed, the decoding device 210, at 435, may transmit an acknowledgment message (e.g., an ACK) to encoding device 205. If the decoding device 210 fails to successfully decode one or more of the soft-combined second CBS, the decoding device 210, at 440, may transmit a number of the soft-combined second CBs that the decoding device 210 failed to decode (e.g., one if at least one of CB2 and CB6 was successfully decoded and two if neither CB2 nor CB6 was successfully decoded).

In some aspects, after the encoding device 205 receives the number of second CBs that the decoding device 210 failed to decode, the encoding device 205 may generate a second retransmission that includes a third TB partitionable into a set of third CBs associated with another RV (e.g., RV2). In such examples, the decoding device 210 may repeat the procedure described herein for the second retransmission.

In some aspects, the decoding scheme 400 may be applied at different granularities. For example, the decoding scheme 400 may be applied at the encoded symbol level instead of the CB level (e.g., the encoded transmission may include a first TB partitionable into a set of encoded symbols ES1, ES2, ES3, ES 4, ES5, and ES6 and 405-440 may be applied to the set of encoded symbols).

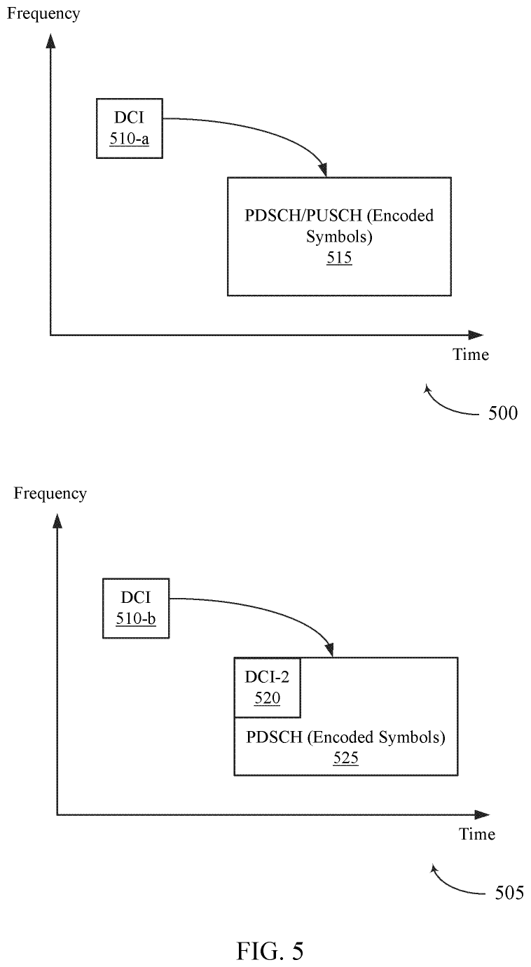

FIG. 5 illustrates an example of resource diagrams 500 and 505 that support information indications for Raptor codes in accordance with one or more aspects of the present disclosure. In some aspects, resource diagrams 500 and 505 may be implemented by aspects of wireless communications system 100. For instance, the resource diagrams 500 and 505 may show examples of DCIs that may indicate SBN and/or ESI for encoded symbols transmitted in a shared channel transmission.

As shown in the resource diagram 500, a DCI 510-a may schedule a shared channel transmission 515, such as a PDSCH or a physical uplink shared channel (PUSCH)), that will be used to transmit one or more encoded symbols. An unused field of the DCI 510-a may be reused or repurposed to indicate the SBN for the one or more encoded symbols. In some aspects, an unused field of the DCI 510-a may be reused or repurposed to indicate ESI for the one or more encoded symbols.

As shown in the resource diagram 505, a DCI 510-b may schedule a downlink shared channel transmission 525 (e.g., a PDSCH), that will be used to transmit one or more encoded symbols. A second DCI 520 may be piggybacked on the downlink shared channel transmission 525 (e.g., the downlink shared channel transmission 525 may include the second DCI 520). The decoding device 210 may decode the downlink shared channel transmission 525 and the second DCI 520 separately, and the second DCI 520 may be decoded with higher reliability than the downlink shared channel transmission 525. The decoding device may decode the encoded symbols in the downlink shared channel transmission 525 based on the indication of the SBN and the ESI transmitted in the second DCI 520.

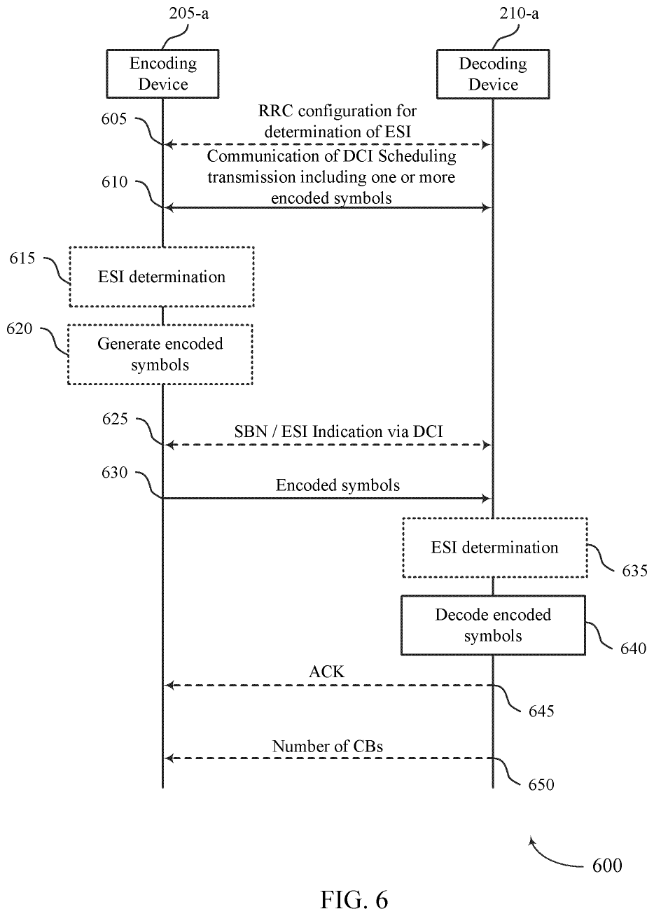

FIG. 6 illustrates an example of a process flow 600 that supports information indications for Raptor codes in accordance with one or more aspects of the present disclosure. In some aspects, process flow 600 may implement aspects of wireless communications system 100. For instance, process flow 600 may be implemented by an encoding device 205-a, which may be an example of an encoding device 205 as described with reference to FIG. 2, and decoding device 210-a, which may be an example of a decoding device 210 as described with reference to FIG. 2. In the following description of the process flow 600, the operations between the encoding device 205-a and the decoding device 210-a may be transmitted in a different order than the example order shown, or the operations performed by the encoding device 205-a and the decoding device 210-a may be performed in different orders or at different times. Some operations may also be omitted from the process flow 600, and other operations may be added to the process flow 600.

At 610, the encoding device 205-a and the decoding device 210-a may participate in communication of a DCI that schedules a transmission that includes one or more encoded symbols associated, via a rateless code, with a respective corresponding set of source symbols of a set of multiple source symbols. For example, the transmission may be a shared channel transmission (e.g., a PDSCH transmission or a PUSCH transmission).

At 625, the encoding device 205-a and the decoding device 210-a may participate in communication of a DCI that indicates an SBN associated with the source block for the set of multiple source symbols. At 630, the encoding device 205-a may transmit the one or more encoded symbols scheduled by the DCI communicated at 610. For example, the encoding device 205-a may generate, from set of multiple source symbols, using a rateless code such as a Raptor code, the encoded symbols at 620 using the SBN and set of ESIs corresponding to the one or more encoded symbols, where the SBN is associated with the source block for the set of multiple source symbols. At 630, the encoding device 205-a may transmit the generated one or more encoded symbols via the shared channel transmission scheduled by the DCI at 610.

In some aspects, the DCI that indicates the SBN at 625 may be the same DCI as the DCI communicated at 610 that schedules the transmission that includes the encoded symbols. In such aspects, the SBN may be indicated in an unused or repurposed field of the DCI. In some aspects, the DCI that indicates the SBN at 625 may be included in the downlink shared channel transmission at 630 (e.g., in cases where the encoding device 205-a is a network entity 105 and the decoding device 210-a is a UE) that includes the one or more encoded symbols.

At 640, the decoding device may decode the encoded symbols based on the indicated SBN.

In some aspects, the DCI that indicates the SBN at 625 may include an explicit indication of a set of ESIs corresponding to the encoded symbols. The decoding device 210-a may decode the one or more encoded symbols based of the indicated set of ESIs. For example, if the DCI that indicates the SBN at 625 is the same DCI as the DCI communicated at 610 that schedules the transmission that includes the encoded symbols, another repurposed or unused field in the DCI may indicate the set of ESIs. As another example, if the DCI that indicates the SBN at 625 is included in the downlink shared channel transmission at 630, the DCI included in the downlink shared channel transmission at 630 may further include an indication of the set of ESIs.

In some aspects, the set of ESIs may be implicitly indicated by the DCI that indicates the SBN at 625, and may be determined by the decoding device 210-a. For example, because in each HARQ process, the SBN may not change, the SBN may be explicitly indicated in a DCI, as described herein, but the set of ESIs may be implicitly indicated and determined by the decoding device 210-a. For example, at 605 the encoding device 205-a and the decoding device 210-a may participate in communication of RRC messaging that configures one or more parameters for ESI calculation. For example, the set of ESIs may be calculated based on information associated with the DCI scheduling the transmission that includes the encoded symbols and/or the DCI that indicates the SBN for the encoded symbols. For example, the information associated with the DCI that may be used to determine the set of ESIs may be the DCI sequence corresponding to the DCI scheduling the transmission that includes the one or more encoded symbols, or the information associated with the DCI that may be used to determine the set of ESIs may be scheduling information for the transmission that includes the one or more encoded symbols. The RRC messaging at 605 may indicate, for example, whether to use the DCI sequence or scheduling information to determine the set of ESIs. Additionally, or alternatively, the RRC messaging at 605 may indicate a function for determining the set of ESIs from the information associated with the DCI.

For example, if the DCI sequence is used to determine the set of ESIs, the DCI sequence may be used as an input to a hash function that outputs the set of ESIs (e.g., ESI=f(DCI sequence)). As another example, if the scheduling information is used to determine the set of ESIs, the scheduling information may be used as an input to a hash function that outputs the set of ESIs (e.g., ESI=f(DCI sequence)). For example, the scheduling information may be the position of a resource block, a number of resource blocks, the SFN, the subframe number, the frequency band, the comb number, the modulation and coding scheme, the resource indicator, or a cell radio network temporary identifier (C-RNTI).

Accordingly, in some aspects, at 615, the encoding device 205-a may determine the set of ESIs for the one or more encoded symbols based on the information associated with the communicated DCI at 610. In such aspects, the encoding device 205-a may generate the encoded symbols at 620 from set of multiple source symbols using the determined set of ESIs. At 635, the decoding device 210-a may determine the set of ESIs for the one or more encoded symbols based on the information associated with the communicated DCI at 610. In such aspects, at 640, the decoding device 210-a may decode the one or more encoded symbols based on the determined set of ESIs. In some aspects, the transmission including the one or more encoded symbols at 630 may be scheduled by a MAC-CE instead of a DCI, and accordingly, the MAC-CE may include an indication of the SBN and information from which the set of ESIs may be determined (e.g., the scheduling information for the transmission including the one or more encoded symbols).

In some aspects, at 645, the decoding device 210-a may transmit an acknowledgment message based on decoding the one or more encoded symbols. The encoding device 205-a may receive the acknowledgment message. In some aspects, at 650, the decoding device 210-a may transmit an indication of a number of one or more of the first CBs that the decoding device 210-a failed to successfully decode.

In some aspects, the encoding device 205-a may transmit a retransmission to decoding device 210-a. The retransmission may include a second TB, where the second TB includes a set of second CBs including a set of second packets associated with a second RV. Each of the set of first CBs may be associated with a respective one of the set of first CBs. In one example, the decoding device 210-a may identify a failure to decode a CB of the set of first CBs that is unassociated with any of the set of second CBs. In such cases, the decoding device 210-a may perform a soft combination procedure using the set of first CBs and the set of second CBs based on identifying the failure and the generated set of encoded symbols. Additionally, the decoding device 210-a may successfully decode the set of second CBs based on performing the soft combination procedure. In another example, the decoding device 210-a may decode a CB of the set of second CBs that is unassociated with any of the set of first CBs. In such examples, the decoding device 210-a may successfully decode the set of second packets based on decoding the CB unassociated with any CB of the set of first CBs.

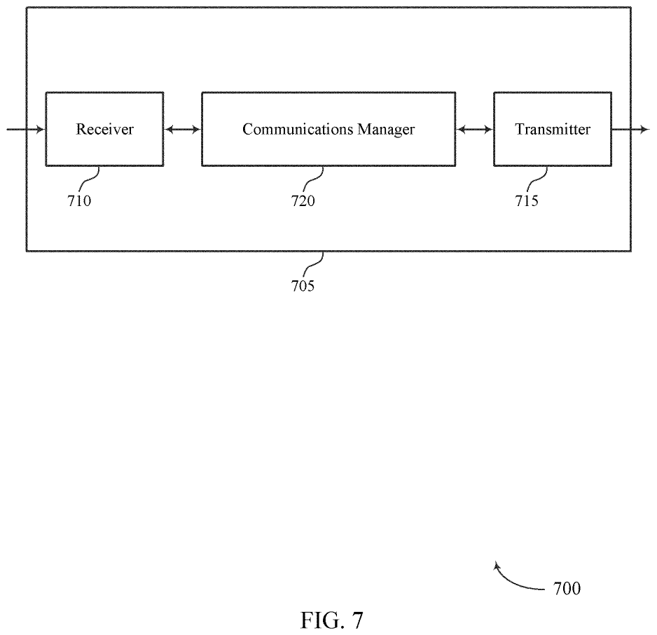

FIG. 7 illustrates a block diagram 700 of a device 705 that supports information indications for Raptor codes in accordance with one or more aspects of the present disclosure. The device 705 may be an example of aspects of a UE 115 or a network entity 105 as described herein. The device 705 may include a receiver 710, a transmitter 715, and a communications manager 720. The device 705 may also include a processor. Each of these components may be in communication with one another (e.g., via one or more buses).

The receiver 710 may provide a means for receiving information such as packets, user data, control information, or any combination thereof associated with various information channels (e.g., control channels, data channels, information channels related to information indications for Raptor codes). Information may be passed on to other components of the device 705. The receiver 710 may utilize a single antenna or a set of multiple antennas.

The transmitter 715 may provide a means for transmitting signals generated by other components of the device 705. For example, the transmitter 715 may transmit information such as packets, user data, control information, or any combination thereof associated with various information channels (e.g., control channels, data channels, information channels related to information indications for Raptor codes). In some aspects, the transmitter 715 may be co-located with a receiver 710 in a transceiver module. The transmitter 715 may utilize a single antenna or a set of multiple antennas.

The communications manager 720, the receiver 710, the transmitter 715, or various combinations thereof or various components thereof may be examples of means for performing various aspects of information indications for Raptor codes as described herein. For example, the communications manager 720, the receiver 710, the transmitter 715, or various combinations or components thereof may support a method for performing one or more of the functions described herein.

In some aspects, the communications manager 720, the receiver 710, the transmitter 715, or various combinations or components thereof may be implemented in hardware (e.g., in communications management circuitry). The hardware may include a processor, a digital signal processor (DSP), a central processing unit (CPU), an application-specific integrated circuit (ASIC), a field-programmable gate array (FPGA) or other programmable logic device, a microcontroller, discrete gate or transistor logic, discrete hardware components, or any combination thereof configured as or otherwise supporting a means for performing the functions described in the present disclosure. In some aspects, a processor and memory coupled with the processor may be configured to perform one or more of the functions described herein (e.g., by executing, by the processor, instructions stored in the memory).

Additionally, or alternatively, in some aspects, the communications manager 720, the receiver 710, the transmitter 715, or various combinations or components thereof may be implemented in code (e.g., as communications management software or firmware) executed by a processor. If implemented in code executed by a processor, the functions of the communications manager 720, the receiver 710, the transmitter 715, or various combinations or components thereof may be performed by a general-purpose processor, a DSP, a CPU, an ASIC, an FPGA, a microcontroller, or any combination of these or other programmable logic devices (e.g., configured as or otherwise supporting a means for performing the functions described in the present disclosure).

In some aspects, the communications manager 720 may be configured to perform various operations (e.g., receiving, obtaining, monitoring, outputting, transmitting) using or otherwise in cooperation with the receiver 710, the transmitter 715, or both. For example, the communications manager 720 may receive information from the receiver 710, send information to the transmitter 715, or be integrated in combination with the receiver 710, the transmitter 715, or both to obtain information, output information, or perform various other operations as described herein.

The communications manager 720 may support wireless communications at a first network node in accordance with examples as disclosed herein. For example, the communications manager 720 may be configured as or otherwise support a means for participating in communication of DCI, where the DCI includes an indication of an SBN associated with a source block for a set of multiple source symbols, where the DCI includes scheduling information for a transmission including one or more encoded symbols derived from the set of multiple source symbols, where the DCI is included in a downlink shared channel transmission that includes the one or more encoded symbols, or the DCI includes the indication in a repurposed field. The communications manager 720 may be configured as or otherwise support a means for receiving the one or more encoded symbols, where each respective encoded symbol of the one or more encoded symbols is associated, via a rateless code, with a respective corresponding set of source symbols of the set of multiple source symbols. The communications manager 720 may be configured as or otherwise support a means for decoding, based on the SBN, the one or more encoded symbols to determine the set of multiple source symbols.

Additionally, or alternatively, the communications manager 720 may support wireless communications at a first network node in accordance with examples as disclosed herein. For example, the communications manager 720 may be configured as or otherwise support a means for participating in communication of DCI, where the DCI includes an indication of an SBN associated with a source block for a set of multiple source symbols, where the DCI includes scheduling information for a transmission including one or more encoded symbols derived from the set of multiple source symbols, where the DCI is included in a downlink shared channel transmission that includes the one or more encoded symbols, or the DCI includes the indication in a repurposed field. The communications manager 720 may be configured as or otherwise support a means for transmitting the one or more encoded symbols, where each respective encoded symbol of the one or more encoded symbols is associated, via a rateless code, with a corresponding set of source symbols of the set of multiple source symbols.

By including or configuring the communications manager 720 in accordance with examples as described herein, the device 705 (e.g., a processor controlling or otherwise coupled with the receiver 710, the transmitter 715, the communications manager 720, or a combination thereof) may support techniques for more efficient utilization of communication resources.

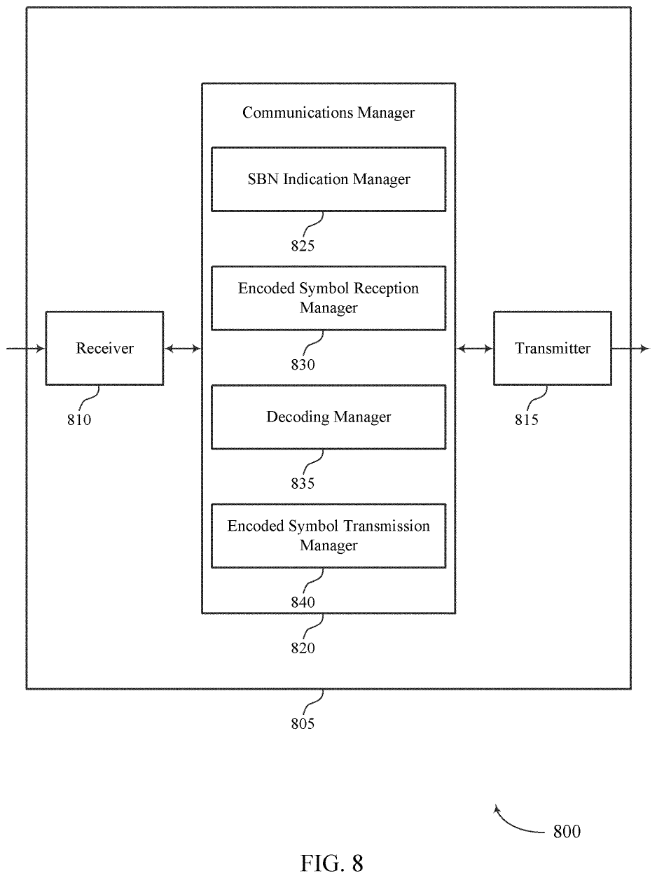

FIG. 8 illustrates a block diagram 800 of a device 805 that supports information indications for Raptor codes in accordance with one or more aspects of the present disclosure. The device 805 may be an example of aspects of a device 705, a UE 115, or a network entity 105 as described herein. The device 805 may include a receiver 810, a transmitter 815, and a communications manager 820. The device 805 may also include a processor. Each of these components may be in communication with one another (e.g., via one or more buses).

The receiver 810 may provide a means for receiving information such as packets, user data, control information, or any combination thereof associated with various information channels (e.g., control channels, data channels, information channels related to information indications for Raptor codes). Information may be passed on to other components of the device 805. The receiver 810 may utilize a single antenna or a set of multiple antennas.

The transmitter 815 may provide a means for transmitting signals generated by other components of the device 805. For example, the transmitter 815 may transmit information such as packets, user data, control information, or any combination thereof associated with various information channels (e.g., control channels, data channels, information channels related to information indications for Raptor codes). In some aspects, the transmitter 815 may be co-located with a receiver 810 in a transceiver module. The transmitter 815 may utilize a single antenna or a set of multiple antennas.

The device 805, or various components thereof, may be an example of means for performing various aspects of information indications for Raptor codes as described herein. For example, the communications manager 820 may include an SBN indication manager 825, an encoded symbol reception manager 830, a decoding manager 835, an encoded symbol transmission manager 840, or any combination thereof. The communications manager 820 may be an example of aspects of a communications manager 720 as described herein. In some aspects, the communications manager 820, or various components thereof, may be configured to perform various operations (e.g., receiving, obtaining, monitoring, outputting, transmitting) using or otherwise in cooperation with the receiver 810, the transmitter 815, or both. For example, the communications manager 820 may receive information from the receiver 810, send information to the transmitter 815, or be integrated in combination with the receiver 810, the transmitter 815, or both to obtain information, output information, or perform various other operations as described herein.

The communications manager 820 may support wireless communications at a first network node in accordance with examples as disclosed herein. The SBN indication manager 825 may be configured as or otherwise support a means for participating in communication of DCI, where the DCI includes an indication of an SBN associated with a source block for a set of multiple source symbols, where the DCI includes scheduling information for a transmission including one or more encoded symbols derived from the set of multiple source symbols, where the DCI is included in a downlink shared channel transmission that includes the one or more encoded symbols, or the DCI includes the indication in a repurposed field. The encoded symbol reception manager 830 may be configured as or otherwise support a means for receiving the one or more encoded symbols, where each respective encoded symbol of the one or more encoded symbols is associated, via a rateless code, with a respective corresponding set of source symbols of the set of multiple source symbols. The decoding manager 835 may be configured as or otherwise support a means for decoding, based on the SBN, the one or more encoded symbols to determine the set of multiple source symbols.

Additionally, or alternatively, the communications manager 820 may support wireless communications at a first network node in accordance with examples as disclosed herein. The SBN indication manager 825 may be configured as or otherwise support a means for participating in communication of DCI, where the DCI includes an indication of an SBN associated with a source block for a set of multiple source symbols, where the DCI includes scheduling information for a transmission including one or more encoded symbols derived from the set of multiple source symbols, where the DCI is included in a downlink shared channel transmission that includes the one or more encoded symbols, or the DCI includes the indication in a repurposed field. The encoded symbol transmission manager 840 may be configured as or otherwise support a means for transmitting the one or more encoded symbols, where each respective encoded symbol of the one or more encoded symbols is associated, via a rateless code, with a corresponding set of source symbols of the set of multiple source symbols.

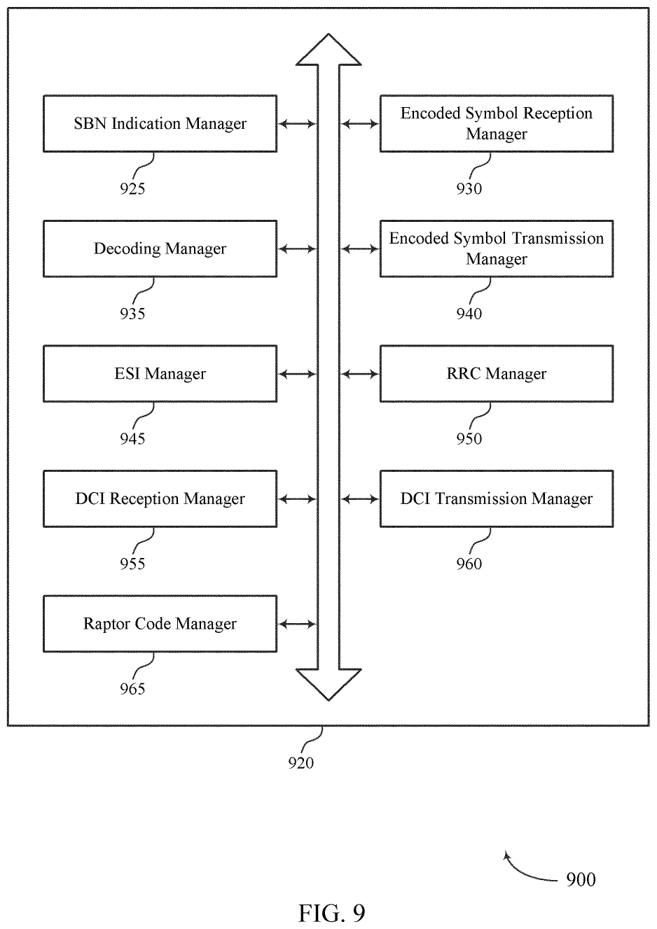

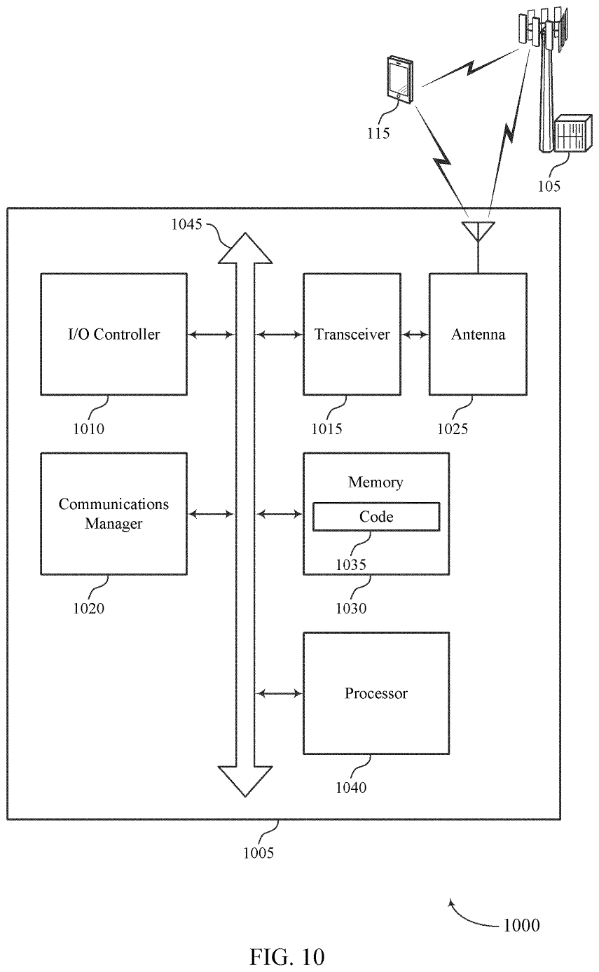

FIG. 9 illustrates a block diagram 900 of a communications manager 920 that supports information indications for Raptor codes in accordance with one or more aspects of the present disclosure. The communications manager 920 may be an example of aspects of a communications manager 720, a communications manager 820, or both, as described herein. The communications manager 920, or various components thereof, may be an example of means for performing various aspects of information indications for Raptor codes as described herein. For example, the communications manager 920 may include an SBN indication manager 925, an encoded symbol reception manager 930, a decoding manager 935, an encoded symbol transmission manager 940, a ESI manager 945, an RRC manager 950, a DCI reception manager 955, a DCI transmission manager 960, a Raptor code manager 965, or any combination thereof. Each of these components may communicate, directly or indirectly, with one another (e.g., via one or more buses) which may include communications within a protocol layer of a protocol stack, communications associated with a logical channel of a protocol stack (e.g., between protocol layers of a protocol stack, within a device, component, or virtualized component associated with a network entity 105, between devices, components, or virtualized components associated with a network entity 105), or any combination thereof.

The communications manager 920 may support wireless communications at a first network node in accordance with examples as disclosed herein. The SBN indication manager 925 may be configured as or otherwise support a means for participating in communication of DCI, where the DCI includes an indication of an SBN associated with a source block for a set of multiple source symbols, where the DCI includes scheduling information for a transmission including one or more encoded symbols derived from the set of multiple source symbols, where the DCI is included in a downlink shared channel transmission that includes the one or more encoded symbols, or the DCI includes the indication in a repurposed field. The encoded symbol reception manager 930 may be configured as or otherwise support a means for receiving the one or more encoded symbols, where each respective encoded symbol of the one or more encoded symbols is associated, via a rateless code, with a respective corresponding set of source symbols of the set of multiple source symbols. The decoding manager 935 may be configured as or otherwise support a means for decoding, based on the SBN, the one or more encoded symbols to determine the set of multiple source symbols.

In some aspects, to support decoding the one or more encoded symbols, the ESI manager 945 may be configured as or otherwise support a means for decoding the one or more encoded symbols based on one or more ESIs, where the DCI includes an indication of the one or more ESIs that correspond to the one or more encoded symbols.

In some aspects, the RRC manager 950 may be configured as or otherwise support a means for participating in communication of an RRC message, where the RRC message indicates one or more parameters. In some aspects, the ESI manager 945 may be configured as or otherwise support a means for determining, based on the one or more parameters and first information included in the DCI, one or more ESIs that correspond to the one or more encoded symbols, where decoding the one or more encoded symbols includes decoding the one or more encoded symbols based on the one or more ESIs.

In some aspects, the first information includes the scheduling information.

In some aspects, the scheduling information includes a position of one or more resource blocks, an SFN, a slot number, or a symbol number.

In some aspects, the first information includes a DCI sequence corresponding to the DCI.

In some aspects, to support participating in the communication of the DCI, the DCI reception manager 955 may be configured as or otherwise support a means for receiving the DCI.

In some aspects, to support participating in the communication of the DCI, the DCI transmission manager 960 may be configured as or otherwise support a means for transmitting the DCI.

In some aspects, to support decoding the one or more encoded symbols, the Raptor code manager 965 may be configured as or otherwise support a means for determining, based on a Raptor code, the set of multiple source symbols from the one or more encoded symbols, where the rateless code is the Raptor code.

Additionally, or alternatively, the communications manager 920 may support wireless communications at a first network node in accordance with examples as disclosed herein. In some aspects, the SBN indication manager 925 may be configured as or otherwise support a means for participating in communication of DCI, where the DCI includes an indication of an SBN associated with a source block for a set of multiple source symbols, where the DCI includes scheduling information for a transmission including one or more encoded symbols derived from the set of multiple source symbols, where the DCI is included in a downlink shared channel transmission that includes the one or more encoded symbols, or the DCI includes the indication in a repurposed field. The encoded symbol transmission manager 940 may be configured as or otherwise support a means for transmitting the one or more encoded symbols, where each respective encoded symbol of the one or more encoded symbols is associated, via a rateless code, with a corresponding set of source symbols of the set of multiple source symbols.

In some aspects, the DCI includes an indication of one or more ESIs that correspond to the one or more encoded symbols.

In some aspects, the RRC manager 950 may be configured as or otherwise support a means for participating in communication of an RRC message, where the RRC message indicates one or more parameters for determination of one or more ESIs that correspond to the one or more encoded symbols.

In some aspects, to support participating in the communication of the DCI, the DCI reception manager 955 may be configured as or otherwise support a means for receiving the DCI.

In some aspects, to support participating in the communication of the DCI, the DCI transmission manager 960 may be configured as or otherwise support a means for transmitting the DCI.

In some aspects, the Raptor code manager 965 may be configured as or otherwise support a means for generating, based on a Raptor code, the one or more encoded symbols from the set of multiple source symbols, where the rateless code is the Raptor code.

FIG. 10 illustrates a diagram of a system 1000 including a device 1005 that supports information indications for Raptor codes in accordance with one or more aspects of the present disclosure. The device 1005 may be an example of or include the components of a device 705, a device 805, or a UE 115 as described herein. The device 1005 may communicate (e.g., wirelessly) with one or more network entities 105, one or more UEs 115, or any combination thereof. The device 1005 may include components for bi-directional voice and data communications including components for transmitting and receiving communications, such as a communications manager 1020, an input/output (I/O) controller 1010, a transceiver 1015, an antenna 1025, a memory 1030, code 1035, and a processor 1040. These components may be in electronic communication or otherwise coupled (e.g., operatively, communicatively, functionally, electronically, electrically) via one or more buses (e.g., a bus 1045).

The I/O controller 1010 may manage input and output signals for the device 1005. The I/O controller 1010 may also manage peripherals not integrated into the device 1005. In some cases, the I/O controller 1010 may represent a physical connection or port to an external peripheral. In some cases, the I/O controller 1010 may utilize an operating system such as iOS®, ANDROID®, MS-DOS®, MS-WINDOWS®, OS/2®, UNIX®, LINUX®, or another known operating system. Additionally, or alternatively, the I/O controller 1010 may represent or interact with a modem, a keyboard, a mouse, a touchscreen, or a similar device. In some cases, the I/O controller 1010 may be implemented as part of a processor, such as the processor 1040. In some cases, a user may interact with the device 1005 via the I/O controller 1010 or via hardware components controlled by the I/O controller 1010.

In some cases, the device 1005 may include a single antenna 1025. However, in some other cases, the device 1005 may have more than one antenna 1025, which may be capable of concurrently transmitting or receiving multiple wireless transmissions. The transceiver 1015 may communicate bi-directionally, via the one or more antennas 1025, wired, or wireless links as described herein. For example, the transceiver 1015 may represent a wireless transceiver and may communicate bi-directionally with another wireless transceiver. The transceiver 1015 may also include a modem to modulate the packets, to provide the modulated packets to one or more antennas 1025 for transmission, and to demodulate packets received from the one or more antennas 1025. The transceiver 1015, or the transceiver 1015 and one or more antennas 1025, may be an example of a transmitter 715, a transmitter 815, a receiver 710, a receiver 810, or any combination thereof or component thereof, as described herein.

The memory 1030 may include random access memory (RAM) and read-only memory (ROM). The memory 1030 may store computer-readable, computer-executable code 1035 including instructions that, when executed by the processor 1040, cause the device 1005 to perform various functions described herein. The code 1035 may be stored in a non-transitory computer-readable medium such as system memory or another type of memory. In some cases, the code 1035 may not be directly executable by the processor 1040 but may cause a computer (e.g., when compiled and executed) to perform functions described herein. In some cases, the memory 1030 may contain, among other things, a basic I/O system (BIOS) which may control basic hardware or software operation such as the interaction with peripheral components or devices.

The processor 1040 may include an intelligent hardware device (e.g., a general-purpose processor, a DSP, a CPU, a microcontroller, an ASIC, an FPGA, a programmable logic device, a discrete gate or transistor logic component, a discrete hardware component, or any combination thereof). In some cases, the processor 1040 may be configured to operate a memory array using a memory controller. In some other cases, a memory controller may be integrated into the processor 1040. The processor 1040 may be configured to execute computer-readable instructions stored in a memory (e.g., the memory 1030) to cause the device 1005 to perform various functions (e.g., functions or tasks supporting information indications for Raptor codes). For example, the device 1005 or a component of the device 1005 may include a processor 1040 and memory 1030 coupled with or to the processor 1040, the processor 1040 and memory 1030 configured to perform various functions described herein.

The communications manager 1020 may support wireless communications at a first network node in accordance with examples as disclosed herein. For example, the communications manager 1020 may be configured as or otherwise support a means for participating in communication of DCI, where the DCI includes an indication of an SBN associated with a source block for a set of multiple source symbols, where the DCI includes scheduling information for a transmission including one or more encoded symbols derived from the set of multiple source symbols, where the DCI is included in a downlink shared channel transmission that includes the one or more encoded symbols, or the DCI includes the indication in a repurposed field. The communications manager 1020 may be configured as or otherwise support a means for receiving the one or more encoded symbols, where each respective encoded symbol of the one or more encoded symbols is associated, via a rateless code, with a respective corresponding set of source symbols of the set of multiple source symbols. The communications manager 1020 may be configured as or otherwise support a means for decoding, based on the SBN, the one or more encoded symbols to determine the set of multiple source symbols.

Additionally, or alternatively, the communications manager 1020 may support wireless communications at a first network node in accordance with examples as disclosed herein. For example, the communications manager 1020 may be configured as or otherwise support a means for participating in communication of DCI, where the DCI includes an indication of an SBN associated with a source block for a set of multiple source symbols, where the DCI includes scheduling information for a transmission including one or more encoded symbols derived from the set of multiple source symbols, where the DCI is included in a downlink shared channel transmission that includes the one or more encoded symbols, or the DCI includes the indication in a repurposed field. The communications manager 1020 may be configured as or otherwise support a means for transmitting the one or more encoded symbols, where each respective encoded symbol of the one or more encoded symbols is associated, via a rateless code, with a corresponding set of source symbols of the set of multiple source symbols.

By including or configuring the communications manager 1020 in accordance with examples as described herein, the device 1005 may support techniques for improved communication reliability, more efficient utilization of communication resources, and improved coordination between devices.

In some aspects, the communications manager 1020 may be configured to perform various operations (e.g., receiving, monitoring, transmitting) using or otherwise in cooperation with the transceiver 1015, the one or more antennas 1025, or any combination thereof. Although the communications manager 1020 is illustrated as a separate component, in some aspects, one or more functions described with reference to the communications manager 1020 may be supported by or performed by the processor 1040, the memory 1030, the code 1035, or any combination thereof. For example, the code 1035 may include instructions executable by the processor 1040 to cause the device 1005 to perform various aspects of information indications for Raptor codes as described herein, or the processor 1040 and the memory 1030 may be otherwise configured to perform or support such operations.

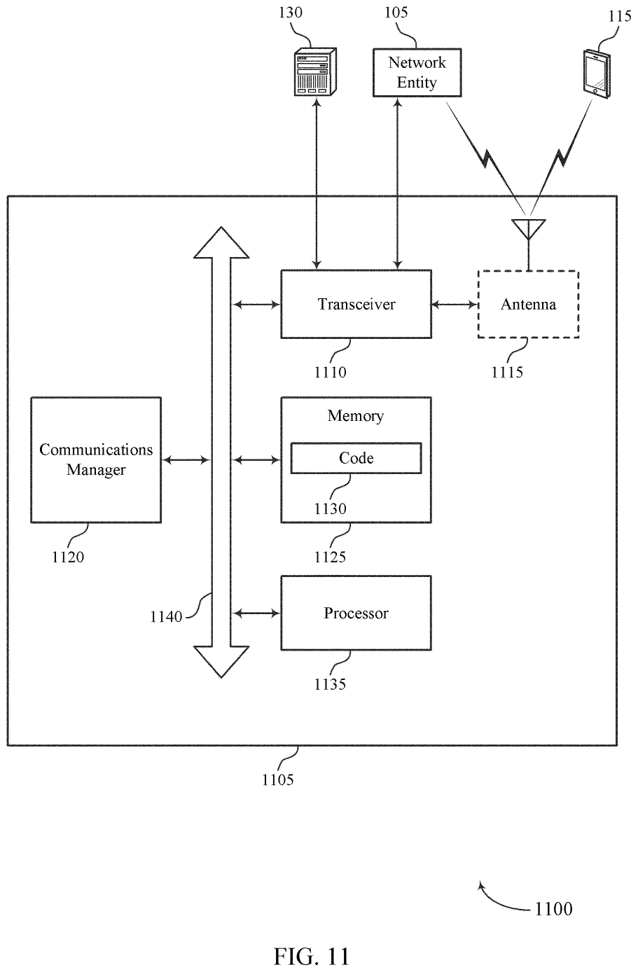

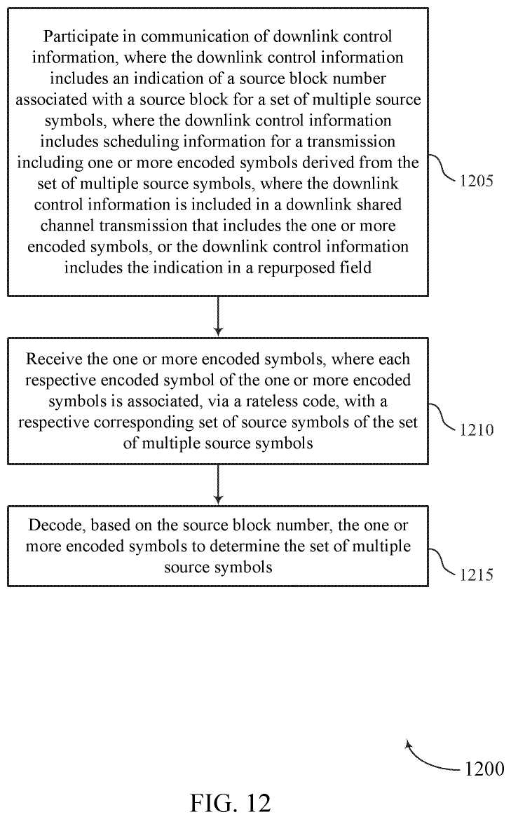

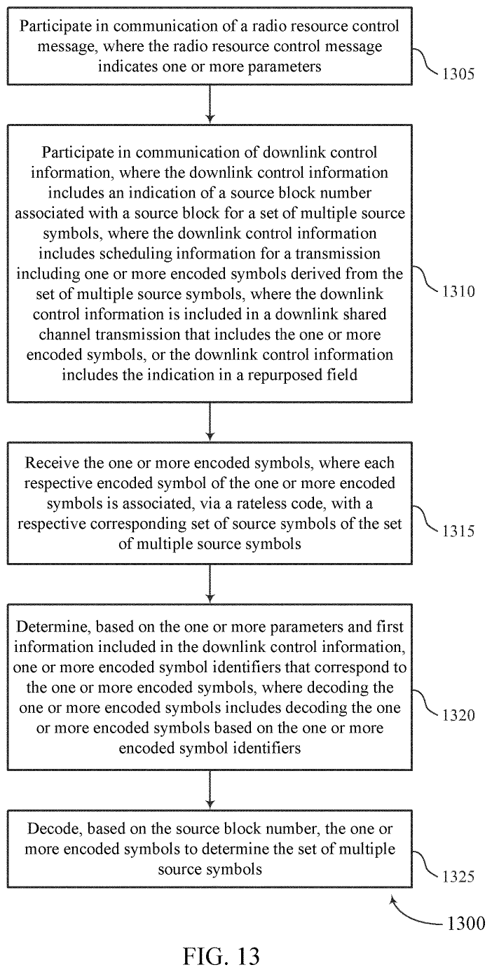

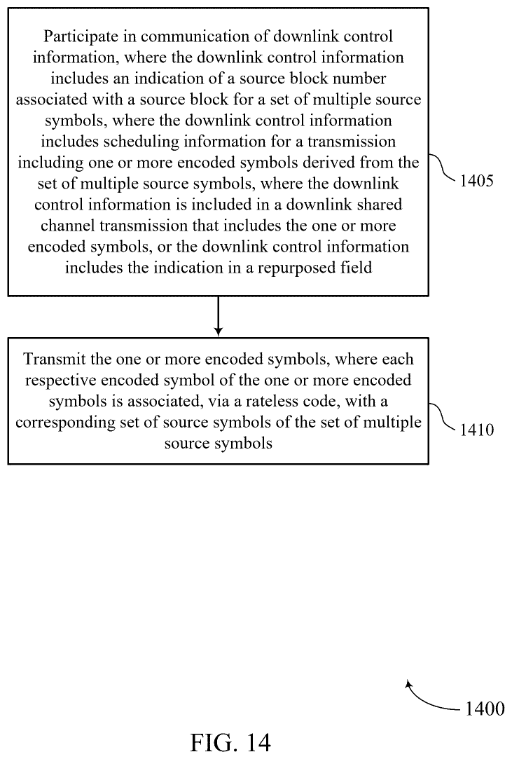

FIG. 11 illustrates a diagram of a system 1100 including a device 1105 that supports information indications for Raptor codes in accordance with one or more aspects of the present disclosure. The device 1105 may be an example of or include the components of a device 705, a device 805, or a network entity 105 as described herein. The device 1105 may communicate with one or more network entities 105, one or more UEs 115, or any combination thereof, which may include communications over one or more wired interfaces, over one or more wireless interfaces, or any combination thereof. The device 1105 may include components that support outputting and obtaining communications, such as a communications manager 1120, a transceiver 1110, an antenna 1115, a memory 1125, code 1130, and a processor 1135. These components may be in electronic communication or otherwise coupled (e.g., operatively, communicatively, functionally, electronically, electrically) via one or more buses (e.g., a bus 1140).

The transceiver 1110 may support bi-directional communications via wired links, wireless links, or both as described herein. In some aspects, the transceiver 1110 may include a wired transceiver and may communicate bi-directionally with another wired transceiver. Additionally, or alternatively, in some aspects, the transceiver 1110 may include a wireless transceiver and may communicate bi-directionally with another wireless transceiver. In some aspects, the device 1105 may include one or more antennas 1115, which may be capable of transmitting or receiving wireless transmissions (e.g., concurrently). The transceiver 1110 may also include a modem to modulate signals, to provide the modulated signals for transmission (e.g., by one or more antennas 1115, by a wired transmitter), to receive modulated signals (e.g., from one or more antennas 1115, from a wired receiver), and to demodulate signals. In some implementations, the transceiver 1110 may include one or more interfaces, such as one or more interfaces coupled with the one or more antennas 1115 that are configured to support various receiving or obtaining operations, or one or more interfaces coupled with the one or more antennas 1115 that are configured to support various transmitting or outputting operations, or a combination thereof. In some implementations, the transceiver 1110 may include or be configured for coupling with one or more processors or memory components that are operable to perform or support operations based on received or obtained information or signals, or to generate information or other signals for transmission or other outputting, or any combination thereof. In some implementations, the transceiver 1110, or the transceiver 1110 and the one or more antennas 1115, or the transceiver 1110 and the one or more antennas 1115 and one or more processors or memory components (for example, the processor 1135, or the memory 1125, or both), may be included in a chip or chip assembly that is installed in the device 1105. In some aspects, the transceiver may be operable to support communications via one or more communications links (e.g., a communication link 125, a backhaul communication link 120, a midhaul communication link 162, a fronthaul communication link 168).

The memory 1125 may include RAM and ROM. The memory 1125 may store computer-readable, computer-executable code 1130 including instructions that, when executed by the processor 1135, cause the device 1105 to perform various functions described herein. The code 1130 may be stored in a non-transitory computer-readable medium such as system memory or another type of memory. In some cases, the code 1130 may not be directly executable by the processor 1135 but may cause a computer (e.g., when compiled and executed) to perform functions described herein. In some cases, the memory 1125 may contain, among other things, a BIOS which may control basic hardware or software operation such as the interaction with peripheral components or devices.

The processor 1135 may include an intelligent hardware device (e.g., a general-purpose processor, a DSP, an ASIC, a CPU, an FPGA, a microcontroller, a programmable logic device, discrete gate or transistor logic, a discrete hardware component, or any combination thereof). In some cases, the processor 1135 may be configured to operate a memory array using a memory controller. In some other cases, a memory controller may be integrated into the processor 1135. The processor 1135 may be configured to execute computer-readable instructions stored in a memory (e.g., the memory 1125) to cause the device 1105 to perform various functions (e.g., functions or tasks supporting information indications for Raptor codes). For example, the device 1105 or a component of the device 1105 may include a processor 1135 and memory 1125 coupled with the processor 1135, the processor 1135 and memory 1125 configured to perform various functions described herein. The processor 1135 may be an example of a cloud-computing platform (e.g., one or more physical nodes and supporting software such as operating systems, virtual machines, or container instances) that may host the functions (e.g., by executing code 1130) to perform the functions of the device 1105. The processor 1135 may be any one or more suitable processors capable of executing scripts or instructions of one or more software programs stored in the device 1105 (such as within the memory 1125). In some implementations, the processor 1135 may be a component of a processing system. A processing system may generally refer to a system or series of machines or components that receives inputs and processes the inputs to produce a set of outputs (which may be passed to other systems or components of, for example, the device 1105). For example, a processing system of the device 1105 may refer to a system including the various other components or subcomponents of the device 1105, such as the processor 1135, or the transceiver 1110, or the communications manager 1120, or other components or combinations of components of the device 1105. The processing system of the device 1105 may interface with other components of the device 1105, and may process information received from other components (such as inputs or signals) or output information to other components. For example, a chip or modem of the device 1105 may include a processing system and one or more interfaces to output information, or to obtain information, or both. The one or more interfaces may be implemented as or otherwise include a first interface configured to output information and a second interface configured to obtain information, or a same interface configured to output information and to obtain information, among other implementations. In some implementations, the one or more interfaces may refer to an interface between the processing system of the chip or modem and a transmitter, such that the device 1105 may transmit information output from the chip or modem. Additionally, or alternatively, in some implementations, the one or more interfaces may refer to an interface between the processing system of the chip or modem and a receiver, such that the device 1105 may obtain information or signal inputs, and the information may be passed to the processing system. A person having ordinary skill in the art will readily recognize that a first interface also may obtain information or signal inputs, and a second interface also may output information or signal outputs.

In some aspects, a bus 1140 may support communications of (e.g., within) a protocol layer of a protocol stack. In some aspects, a bus 1140 may support communications associated with a logical channel of a protocol stack (e.g., between protocol layers of a protocol stack), which may include communications performed within a component of the device 1105, or between different components of the device 1105 that may be co-located or located in different locations (e.g., where the device 1105 may refer to a system in which one or more of the communications manager 1120, the transceiver 1110, the memory 1125, the code 1130, and the processor 1135 may be located in one of the different components or divided between different components).

In some aspects, the communications manager 1120 may manage aspects of communications with a core network 130 (e.g., via one or more wired or wireless backhaul links). For example, the communications manager 1120 may manage the transfer of data communications for client devices, such as one or more UEs 115. In some aspects, the communications manager 1120 may manage communications with other network entities 105, and may include a controller or scheduler for controlling communications with UEs 115 in cooperation with other network entities 105. In some aspects, the communications manager 1120 may support an X2 interface within an LTE/LTE-A wireless communications network technology to provide communication between network entities 105.

The communications manager 1120 may support wireless communications at a first network node in accordance with examples as disclosed herein. For example, the communications manager 1120 may be configured as or otherwise support a means for participating in communication of DCI, where the DCI includes an indication of an SBN associated with a source block for a set of multiple source symbols, where the DCI includes scheduling information for a transmission including one or more encoded symbols derived from the set of multiple source symbols, where the DCI is included in a downlink shared channel transmission that includes the one or more encoded symbols, or the DCI includes the indication in a repurposed field. The communications manager 1120 may be configured as or otherwise support a means for receiving the one or more encoded symbols, where each respective encoded symbol of the one or more encoded symbols is associated, via a rateless code, with a respective corresponding set of source symbols of the set of multiple source symbols. The communications manager 1120 may be configured as or otherwise support a means for decoding, based on the SBN, the one or more encoded symbols to determine the set of multiple source symbols.

Additionally, or alternatively, the communications manager 1120 may support wireless communications at a first network node in accordance with examples as disclosed herein. For example, the communications manager 1120 may be configured as or otherwise support a means for participating in communication of DCI, where the DCI includes an indication of an SBN associated with a source block for a set of multiple source symbols, where the DCI includes scheduling information for a transmission including one or more encoded symbols derived from the set of multiple source symbols, where the DCI is included in a downlink shared channel transmission that includes the one or more encoded symbols, or the DCI includes the indication in a repurposed field. The communications manager 1120 may be configured as or otherwise support a means for transmitting the one or more encoded symbols, where each respective encoded symbol of the one or more encoded symbols is associated, via a rateless code, with a corresponding set of source symbols of the set of multiple source symbols.

By including or configuring the communications manager 1120 in accordance with examples as described herein, the device 1105 may support techniques for improved communication reliability, more efficient utilization of communication resources, and improved coordination between devices.

In some aspects, the communications manager 1120 may be configured to perform various operations (e.g., receiving, obtaining, monitoring, outputting, transmitting) using or otherwise in cooperation with the transceiver 1110, the one or more antennas 1115 (e.g., where applicable), or any combination thereof. Although the communications manager 1120 is illustrated as a separate component, in some aspects, one or more functions described with reference to the communications manager 1120 may be supported by or performed by the transceiver 1110, the processor 1135, the memory 1125, the code 1130, or any combination thereof. For example, the code 1130 may include instructions executable by the processor 1135 to cause the device 1105 to perform various aspects of information indications for Raptor codes as described herein, or the processor 1135 and the memory 1125 may be otherwise configured to perform or support such operations.

FIG. 12 illustrates a flowchart showing a method 1200 that supports information indications for Raptor codes in accordance with one or more aspects of the present disclosure. The operations of the method 1200 may be implemented by a UE or a network entity or its components as described herein. For example, the operations of the method 1200 may be performed by a UE 115 or a network entity as described with reference to FIGS. 1 through 11. In some aspects, a UE or a network entity may execute a set of instructions to control the functional elements of the UE or the network entity to perform the described functions. Additionally, or alternatively, the UE or the network entity may perform aspects of the described functions using special-purpose hardware.

At 1205, the method may include participating in communication of DCI, where the DCI includes an indication of an SBN associated with a source block for a set of multiple source symbols, where the DCI includes scheduling information for a transmission including one or more encoded symbols derived from the set of multiple source symbols, where the DCI is included in a downlink shared channel transmission that includes the one or more encoded symbols, or the DCI includes the indication in a repurposed field. The operations of 1205 may be performed in accordance with examples as disclosed herein. In some aspects, aspects of the operations of 1205 may be performed by an SBN indication manager 925 as described with reference to FIG. 9.

At 1210, the method may include receiving the one or more encoded symbols, where each respective encoded symbol of the one or more encoded symbols is associated, via a rateless code, with a respective corresponding set of source symbols of the set of multiple source symbols. The operations of 1210 may be performed in accordance with examples as disclosed herein. In some aspects, aspects of the operations of 1210 may be performed by an encoded symbol reception manager 930 as described with reference to FIG. 9.

At 1215, the method may include decoding, based on the SBN, the one or more encoded symbols to determine the set of multiple source symbols. The operations of 1215 may be performed in accordance with examples as disclosed herein. In some aspects, aspects of the operations of 1215 may be performed by a decoding manager 935 as described with reference to FIG. 9.

FIG. 13 illustrates a flowchart showing a method 1300 that supports information indications for Raptor codes in accordance with one or more aspects of the present disclosure. The operations of the method 1300 may be implemented by a UE or a network entity or its components as described herein. For example, the operations of the method 1300 may be performed by a UE 115 or a network entity as described with reference to FIGS. 1 through 11. In some aspects, a UE or a network entity may execute a set of instructions to control the functional elements of the UE or the network entity to perform the described functions. Additionally, or alternatively, the UE or the network entity may perform aspects of the described functions using special-purpose hardware.

At 1305, the method may include participating in communication of an RRC message, where the RRC message indicates one or more parameters. The operations of 1305 may be performed in accordance with examples as disclosed herein. In some aspects, aspects of the operations of 1305 may be performed by an RRC manager 950 as described with reference to FIG. 9.

At 1310, the method may include participating in communication of DCI, where the DCI includes an indication of an SBN associated with a source block for a set of multiple source symbols, where the DCI includes scheduling information for a transmission including one or more encoded symbols derived from the set of multiple source symbols, where the DCI is included in a downlink shared channel transmission that includes the one or more encoded symbols, or the DCI includes the indication in a repurposed field. The operations of 1310 may be performed in accordance with examples as disclosed herein. In some aspects, aspects of the operations of 1310 may be performed by an SBN indication manager 925 as described with reference to FIG. 9.

At 1315, the method may include receiving the one or more encoded symbols, where each respective encoded symbol of the one or more encoded symbols is associated, via a rateless code, with a respective corresponding set of source symbols of the set of multiple source symbols. The operations of 1315 may be performed in accordance with examples as disclosed herein. In some aspects, aspects of the operations of 1315 may be performed by an encoded symbol reception manager 930 as described with reference to FIG. 9.

At 1320, the method may include determining, based on the one or more parameters and first information included in the DCI, one or more ESIs that correspond to the one or more encoded symbols. The operations of 1320 may be performed in accordance with examples as disclosed herein. In some aspects, aspects of the operations of 1320 may be performed by a ESI manager 945 as described with reference to FIG. 9.

At 1325, the method may include decoding, based on the SBN, the one or more encoded symbols to determine the set of multiple source symbols, where decoding the one or more encoded symbols includes decoding the one or more encoded symbols based on the one or more ESIs. The operations of 1325 may be performed in accordance with examples as disclosed herein. In some aspects, aspects of the operations of 1325 may be performed by a decoding manager 935 as described with reference to FIG. 9.

FIG. 14 illustrates a flowchart showing a method 1400 that supports information indications for Raptor codes in accordance with one or more aspects of the present disclosure. The operations of the method 1400 may be implemented by a UE or a network entity or its components as described herein. For example, the operations of the method 1400 may be performed by a UE 115 or a network entity as described with reference to FIGS. 1 through 11. In some aspects, a UE or a network entity may execute a set of instructions to control the functional elements of the UE or the network entity to perform the described functions. Additionally, or alternatively, the UE or the network entity may perform aspects of the described functions using special-purpose hardware.

At 1405, the method may include participating in communication of DCI, where the DCI includes an indication of an SBN associated with a source block for a set of multiple source symbols, where the DCI includes scheduling information for a transmission including one or more encoded symbols derived from the set of multiple source symbols, where the DCI is included in a downlink shared channel transmission that includes the one or more encoded symbols, or the DCI includes the indication in a repurposed field. The operations of 1405 may be performed in accordance with examples as disclosed herein. In some aspects, aspects of the operations of 1405 may be performed by an SBN indication manager 925 as described with reference to FIG. 9.

At 1410, the method may include transmitting the one or more encoded symbols, where each respective encoded symbol of the one or more encoded symbols is associated, via a rateless code, with a corresponding set of source symbols of the set of multiple source symbols. The operations of 1410 may be performed in accordance with examples as disclosed herein. In some aspects, aspects of the operations of 1410 may be performed by an encoded symbol transmission manager 940 as described with reference to FIG. 9.

The following provides an overview of aspects of the present disclosure:

Aspect 1: A method for wireless communications at a first network node, comprising: participating in communication of DCI, wherein the DCI includes an indication of a SBN associated with a source block for a plurality of source symbols, wherein the DCI includes scheduling information for a transmission including one or more encoded symbols derived from the plurality of source symbols, wherein the DCI is included in a downlink shared channel transmission that includes the one or more encoded symbols, or the DCI includes the indication in a repurposed field; receiving the one or more encoded symbols, wherein each respective encoded symbol of the one or more encoded symbols is associated, via a rateless code, with a respective corresponding set of source symbols of the plurality of source symbols; and decoding, based on the SBN, the one or more encoded symbols to determine the plurality of source symbols.

Aspect 2: The method of aspect 1, wherein decoding the one or more encoded symbols comprises: decoding the one or more encoded symbols based on one or more ESIs, wherein the DCI includes an indication of the one or more ESIs that correspond to the one or more encoded symbols.

Aspect 3: The method of aspect 1, further comprising: participating in communication of a RRC message, wherein the RRC message indicates one or more parameters; and determining, based on the one or more parameters and first information included in the DCI, one or more ESIs that correspond to the one or more encoded symbols, wherein decoding the one or more encoded symbols comprises decoding the one or more encoded symbols based on the one or more ESIs.

Aspect 4: The method of aspect 3, wherein the first information comprises the scheduling information.

Aspect 5: The method of aspect 4, wherein the scheduling information comprises a position of one or more resource blocks, a system frame number, a slot number, or a symbol number.

Aspect 6: The method of aspect 3, wherein the first information comprises a DCI sequence corresponding to the DCI.

Aspect 7: The method of any of aspects 1 through 6, wherein participating in the communication of the DCI comprises: receiving the DCI.

Aspect 8: The method of any of aspects 1 through 6, wherein participating in the communication of the DCI comprises: transmitting the DCI.

Aspect 9: The method of any of aspects 1 through 8, wherein decoding the one or more encoded symbols comprises: determining, based on a Raptor code, the plurality of source symbols from the one or more encoded symbols, wherein the rateless code is the Raptor code.

Aspect 10: A method for wireless communications at a first network node, comprising: participating in communication of DCI, wherein the DCI includes an indication of a SBN associated with a source block for a plurality of source symbols, wherein the DCI includes scheduling information for a transmission including one or more encoded symbols derived from the plurality of source symbols, wherein the DCI is included in a downlink shared channel transmission that includes the one or more encoded symbols, or the DCI includes the indication in a repurposed field; and transmitting the one or more encoded symbols, wherein each respective encoded symbol of the one or more encoded symbols is associated, via a rateless code, with a corresponding set of source symbols of the plurality of source symbols.

Aspect 11: The method of aspect 10, wherein the DCI includes an indication of one or more ESIs that correspond to the one or more encoded symbols.

Aspect 12: The method of aspect 10, further comprising: participating in communication of a RRC message, wherein the RRC message indicates one or more parameters for determination of one or more ESIs that correspond to the one or more encoded symbols.

Aspect 13: The method of any of aspects 10 through 12, wherein participating in the communication of the DCI comprises: receiving the DCI.

Aspect 14: The method of any of aspects 10 through 12, wherein participating in the communication of the DCI comprises: transmitting the DCI.

Aspect 15: The method of any of aspects 10 through 14, further comprising: generating, based on a Raptor code, the one or more encoded symbols from the plurality of source symbols, wherein the rateless code is the Raptor code.

Aspect 16: A first network node for wireless communication, comprising: a memory; and at least one processor coupled to the memory, wherein the at least one processor is configured to perform a method of any of aspects 1 through 9.

Aspect 17: An apparatus for wireless communications at a first network node, comprising at least one means for performing a method of any of aspects 1 through 9.

Aspect 18: A non-transitory computer-readable medium having code for wireless communication stored thereon that, when executed by a network node, causes the network node to perform a method of any of aspects 1 through 9.

Aspect 19: A first network node for wireless communication, comprising: a memory; and at least one processor coupled to the memory, wherein the at least one processor is configured to perform a method of any of aspects 10 through 15.

Aspect 20: An apparatus for wireless communications at a first network node, comprising at least one means for performing a method of any of aspects 10 through 15.

Aspect 21: A non-transitory computer-readable medium having code for wireless communication stored thereon that, when executed by a network node, causes the network node to perform a method of any of aspects 10 through 15.

The methods described herein describe possible implementations, and the operations and the steps may be rearranged or otherwise modified and that other implementations are possible. Further, aspects from two or more of the methods may be combined.

Although aspects of an LTE, LTE-A, LTE-A Pro, or NR system may be described for purposes of example, and LTE, LTE-A, LTE-A Pro, or NR terminology may be used in much of the description, the techniques described herein are applicable beyond LTE, LTE-A, LTE-A Pro, or NR networks. For example, the described techniques may be applicable to various other wireless communications systems such as Ultra Mobile Broadband (UMB), Institute of Electrical and Electronics Engineers (IEEE) 802.11 (Wi-Fi), IEEE 802.16 (WiMAX), IEEE 802.20, Flash-OFDM, as well as other systems and radio technologies not explicitly mentioned herein.

Information and signals described herein may be represented using any of a variety of different technologies and techniques. For example, data, instructions, commands, information, signals, bits, symbols, and chips that may be referenced throughout the description may be represented by voltages, currents, electromagnetic waves, magnetic fields or particles, optical fields or particles, or any combination thereof.

The various illustrative blocks and components described in connection with the disclosure herein may be implemented or performed using a general-purpose processor, a DSP, an ASIC, a CPU, an FPGA or other programmable logic device, discrete gate or transistor logic, discrete hardware components, or any combination thereof designed to perform the functions described herein. A general-purpose processor may be a microprocessor but, in the alternative, the processor may be any processor, controller, microcontroller, or state machine. A processor may also be implemented as a combination of computing devices (e.g., a combination of a DSP and a microprocessor, multiple microprocessors, one or more microprocessors in conjunction with a DSP core, or any other such configuration).

The functions described herein may be implemented using hardware, software executed by a processor, firmware, or any combination thereof. If implemented using software executed by a processor, the functions may be stored as or transmitted using one or more instructions or code of a computer-readable medium. Other examples and implementations are within the scope of the disclosure and claims. For example, due to the nature of software, functions described herein may be implemented using software executed by a processor, hardware, firmware, hardwiring, or combinations of any of these. Features implementing functions may also be physically located at various positions, including being distributed such that portions of functions are implemented at different physical locations.

Computer-readable media includes both non-transitory computer storage media and communication media including any medium that facilitates transfer of a computer program from one location to another. A non-transitory storage medium may be any available medium that may be accessed by a general-purpose or special-purpose computer. By way of example, and not limitation, non-transitory computer-readable media may include RAM, ROM, electrically erasable programmable ROM (EEPROM), flash memory, compact disk (CD) ROM or other optical disk storage, magnetic disk storage or other magnetic storage devices, or any other non-transitory medium that may be used to carry or store desired program code means in the form of instructions or data structures and that may be accessed by a general-purpose or special-purpose computer, or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of computer-readable medium. Disk and disc, as used herein, include CD, laser disc, optical disc, digital versatile disc (DVD), floppy disk and Blu-ray disc. Disks may reproduce data magnetically, and discs may reproduce data optically using lasers. Combinations of the above are also included within the scope of computer-readable media.

As used herein, the term “or” is an inclusive “or” unless limiting language is used relative to the alternatives listed. For example, reference to “X being based on A or B” shall be construed as including within its scope X being based on A, X being based on B, and X being based on A and B. In this regard, reference to “X being based on A or B” refers to “at least one of A or B” or “one or more of A or B” due to “or” being inclusive. Similarly, reference to “X being based on A, B, or C” shall be construed as including within its scope X being based on A, X being based on B, X being based on C, X being based on A and B, X being based on A and C, X being based on B and C, and X being based on A, B, and C. In this regard, reference to “X being based on A, B, or C” refers to “at least one of A, B, or C” or “one or more of A, B, or C” due to “or” being inclusive. As an example of limiting language, reference to “X being based on only one of A or B” shall be construed as including within its scope X being based on A as well as X being based on B, but not X being based on A and B. Also, as used herein, the phrase “based on” shall not be construed as a reference to a closed set of information, one or more conditions, one or more factors, or the like. In other words, the phrase “based on A” (where “A” may be information, a condition, a factor, or the like) shall be construed as “based at least on A” unless specifically recited differently. Also, as used herein, the phrase “a set” shall be construed as including the possibility of a set with one member. That is, the phrase “a set” shall be construed in the same manner as “one or more” or “at least one of.”

The term “determine” or “determining” encompasses a variety of actions and, therefore, “determining” can include calculating, computing, processing, deriving, investigating, looking up (such as via looking up in a table, a database or another data structure), ascertaining and the like. Also, “determining” can include receiving (e.g., receiving information), accessing (e.g., accessing data stored in memory) and the like. Also, “determining” can include resolving, obtaining, selecting, choosing, establishing, and other such similar actions.

In the figures, similar components or features may have the same reference label. Further, various components of the same type may be distinguished by following the reference label by a dash and a second label that distinguishes among the similar components. If just the first reference label is used in the specification, the description is applicable to any one of the similar components having the same first reference label irrespective of the second reference label, or other subsequent reference label.

The description set forth herein, in connection with the drawings, describes example configurations and does not represent all the examples that may be implemented or that are within the scope of the claims. The term “aspect” or “example” used herein means “serving as an aspect, example, instance, or illustration,” and not “preferred” or “advantageous over other aspects.” The detailed description includes specific details for the purpose of providing an understanding of the described techniques. These techniques, however, may be practiced without these specific details. In some instances, structures and devices are shown in block diagram form in order to avoid obscuring the concepts of the described examples.

The description herein is provided to enable a person having ordinary skill in the art to make or use the disclosure. Various modifications to the disclosure will be apparent to a person having ordinary skill in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

1. A first network node for wireless communication, comprising:
a memory; and
at least one processor coupled to the memory, wherein the at least one processor is configured to:
participate in communication of downlink control information, wherein the downlink control information includes an indication of a source block number associated with a source block for a plurality of source symbols, wherein the downlink control information includes scheduling information for a transmission including one or more encoded symbols derived from the plurality of source symbols, wherein the downlink control information is included in a downlink shared channel transmission that includes the one or more encoded symbols, or the downlink control information includes the indication in a repurposed field;
receive the one or more encoded symbols, wherein each respective encoded symbol of the one or more encoded symbols is associated, via a rateless code, with a respective corresponding set of source symbols of the plurality of source symbols; and
decode, based on the source block number, the one or more encoded symbols to determine the plurality of source symbols.

2. The first network node of claim 1, wherein the downlink control information includes an indication of one or more encoded symbol identifiers that correspond to the one or more encoded symbols, and wherein to decode the one or more encoded symbols, the at least one processor is configured to decode the one or more encoded symbols based on the one or more encoded symbol identifiers.

3. The first network node of claim 1, wherein the at least one processor is further configured to:
participate in communication of a radio resource control message, wherein the radio resource control message indicates one or more parameters; and
determine, based on the one or more parameters and first information included in the downlink control information, one or more encoded symbol identifiers that correspond to the one or more encoded symbols, wherein to decode the one or more encoded symbols, the at least one processor is configured to decode the one or more encoded symbols based on the one or more encoded symbol identifiers.

4. The first network node of claim 3, wherein the first information comprises the scheduling information.

5. The first network node of claim 4, wherein the scheduling information comprises a position of one or more resource blocks, a system frame number, a slot number, or a symbol number.

6. The first network node of claim 3, wherein the first information comprises a downlink control information sequence corresponding to the downlink control information.

7. The first network node of claim 1, wherein to participate in communication of the downlink control information, the at least one processor is configured to receive the downlink control information.

8. The first network node of claim 1, wherein to participate in communication of the downlink control information, the at least one processor is configured to transmit the downlink control information.

9. The first network node of claim 1, wherein to decode the one or more encoded symbols, the at least one processor is configured to:
determine, based on a Raptor code, the plurality of source symbols from the one or more encoded symbols, wherein the rateless code is the Raptor code.

10. A first network node for wireless communication, comprising:
a memory; and
at least one processor coupled to the memory, wherein the at least one processor is configured to:
participate in communication of downlink control information, wherein the downlink control information includes an indication of a source block number associated with a source block for a plurality of source symbols, wherein the downlink control information includes scheduling information for a transmission including one or more encoded symbols derived from the plurality of source symbols, wherein the downlink control information is included in a downlink shared channel transmission that includes the one or more encoded symbols, or the downlink control information includes the indication in a repurposed field; and
transmit the one or more encoded symbols, wherein each respective encoded symbol of the one or more encoded symbols is associated, via a rateless code, with a corresponding set of source symbols of the plurality of source symbols.

11. The first network node of claim 10, wherein the downlink control information includes an indication of one or more encoded symbol identifiers that correspond to the one or more encoded symbols.

12. The first network node of claim 10, wherein the at least one processor is further configured to:
participate in communication of a radio resource control message, wherein the radio resource control message indicates one or more parameters for determination of one or more encoded symbol identifiers that correspond to the one or more encoded symbols.

13. The first network node of claim 10, wherein to participate in communication of the downlink control information, the at least one processor is configured to receive the downlink control information.

14. The first network node of claim 10, wherein to participate in communication of the downlink control information, the at least one processor is configured to transmit the downlink control information.

15. The first network node of claim 10, wherein the at least one processor is further configured to:
generate, based on a Raptor code, the one or more encoded symbols from the plurality of source symbols, wherein the rateless code is the Raptor code.

16. A method for wireless communications at a first network node, comprising:
participating in communication of downlink control information, wherein the downlink control information includes an indication of a source block number associated with a source block for a plurality of source symbols, wherein the downlink control information includes scheduling information for a transmission including one or more encoded symbols derived from the plurality of source symbols, wherein the downlink control information is included in a downlink shared channel transmission that includes the one or more encoded symbols, or the downlink control information includes the indication in a repurposed field;
receiving the one or more encoded symbols, wherein each respective encoded symbol of the one or more encoded symbols is associated, via a rateless code, with a respective corresponding set of source symbols of the plurality of source symbols; and
decoding, based on the source block number, the one or more encoded symbols to determine the plurality of source symbols.

17. The method of claim 16, wherein decoding the one or more encoded symbols comprises:
decoding the one or more encoded symbols based on one or more encoded symbol identifiers, wherein the downlink control information includes an indication of the one or more encoded symbol identifiers that correspond to the one or more encoded symbols.

18. The method of claim 16, further comprising:
participating in communication of a radio resource control message, wherein the radio resource control message indicates one or more parameters; and
determining, based on the one or more parameters and first information included in the downlink control information, one or more encoded symbol identifiers that correspond to the one or more encoded symbols, wherein decoding the one or more encoded symbols comprises decoding the one or more encoded symbols based on the one or more encoded symbol identifiers.

19. The method of claim 18, wherein the first information comprises the scheduling information.

20. The method of claim 19, wherein the scheduling information comprises a position of one or more resource blocks, a system frame number, a slot number, or a symbol number.

21-30. (canceled)
